(19) United States
(12) Patent Application Publication
(10) Pub. No.: US 2026/0239938 A1
(43) Pub. Date: Aug. 13, 2026

(54) STACKED DEVICE AND METHOD FOR FORMING VERTICAL INTERCONNECT STRUCTURE IN STACKED DEVICE USING CYCLIC DEPOSITION AND ETCHING PROCESSES

(71) Applicant: TAIWAN SEMICONDUCTOR MANUFACTURING COMPANY, LTD., Hsinchu (TW)

(72) Inventors: Meng-Hsi CHUANG, Hsinchu City (TW); Tzu Pei CHEN, Taipei City (TW); Sung-Li WANG, Hsinchu County (TW); Pinyen LIN, Rochester, NY (US)

(73) Assignee: TAIWAN SEMICONDUCTOR MANUFACTURING COMPANY, LTD., Hsinchu (TW)

(21) Appl. No.: 19/050,804

(22) Filed: Feb. 11, 2025

(51) Int. Cl. H01L 21/762; H01L 21/311; H01L 21/768; H10D 30/01; H10D 30/43; H10D 30/67; H10D 62/10; H10D 64/01; H10D 84/85

(52) U.S. Cl. CPC H10W 10/014; H10D 30/43; H10D 30/6757; H10D 84/853; H10P 50/283; H10W 10/17; H10W 20/076; H10D 30/014; H10D 62/121; H10D 64/017

(57) ABSTRACT

A method includes forming a bottom transistor and a top transistor over the bottom transistor. A trench is formed in gate structures of the bottom transistor and the top transistor. A dielectric liner is deposited in the trench. A deposition process is performed to deposit a conductive material in the trench and over the dielectric liner. The conductive material exposes an inner sidewall of the dielectric liner. An etching process is performed to remove parts of the conductive material on sidewall portions of the dielectric liner. A part of the conductive material remains at a bottom of the trench. The deposition process and the etching process are repeatedly performed until the conductive material fills the trench. A part of the dielectric liner and a part of the conductive material outside the trench are removed to form a local interconnect structure including the dielectric liner and the conductive material.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an integrated circuit structure (or a semiconductor device) in accordance with some embodiments of the present disclosure.

FIGS. 2-16D illustrate perspective views and cross-sectional views of intermediate stages in the formation of the integrated circuit structure (or the semiconductor device) in accordance with some embodiments of the present disclosure.

FIG. 17 is a perspective view of an integrated circuit structure (or a semiconductor device) in accordance with some embodiments of the present disclosure.

FIGS. 18A-18D are cross-sectional view of the integrated circuit structure (or the semiconductor device) in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “etch selectivity” refers to the ratio of the etch rates of two different materials under the same etching conditions. As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region. As used herein, source/drain region(s) may refer to a source or a drain, individually or collectively dependent upon the context.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to methods of forming integrated circuit structures. More particularly, some embodiments of the present disclosure are related to method for forming stacked GAA devices including a vertical local interconnect (VLI) structure without voids therein by performing cyclic deposition and etching processes for conductive materials of the VLI structure.

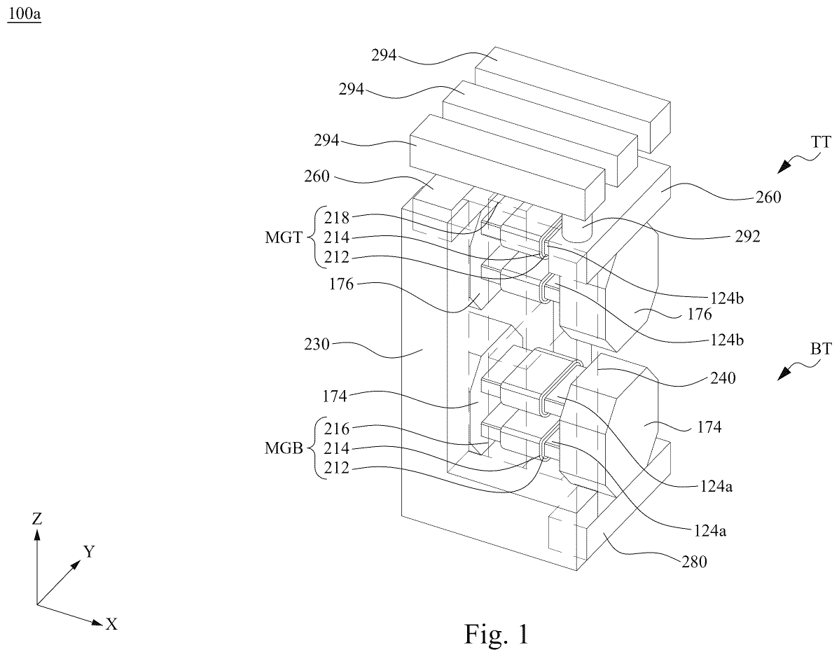

FIG. 1 is a perspective view of an integrated circuit structure (or a semiconductor device) 100a in accordance with some embodiments of the present disclosure. In the present disclosure, a semiconductor device 100a is provided, and its manufacturing method will be disclosed in the following discussion. In addition to the semiconductor device 100a, FIG. 1 depicts X-axis, Y-axis, and Z-axis directions. In the semiconductor device 100a, a bottom transistor BT is disposed over a substrate (not shown), and a top transistor TT is disposed vertically above the bottom transistor BT. In some embodiments, the bottom transistor BT and the top transistor TT each may be a field effect transistor (FET) and may both include gate-all-around (GAA) configuration, and thus the bottom transistor BT and the top transistor TT can also be referred to as GAA FETs. The bottom transistor BT includes channel structures 124a vertically stacked one above another, a gate structure MGB wrapping around each of the channel structures 124a, and lower source/drain epitaxial structures 174 on opposite ends of each of the channel structures 124a. Similarly, the top transistor TT includes channel structures 124b vertically stacked one above another, a gate structure MGT wrapping around each of the channel structures 124b, and upper source/drain epitaxial structures 176 on opposite ends of each of the channel structures 124b.

The gate structure MGB may include an interfacial layer 212, a high-k gate dielectric layer 214, and a work function metal layer 216. Similarly, the gate structure MGT may include the interfacial layer 212, the high-k gate dielectric layer 214, and a work function metal layer 218. In some embodiments, the bottom transistor BT has a first conductivity type (e.g., p-type) and the top transistor TT has a second conductivity type (e.g., n-type) different from the first conductivity type. In some embodiments, the bottom transistor BT can be referred to as a P-FET, and the top transistor TT can be referred to as an N-FET.

The semiconductor device 100a further includes a VLI structure 230. The VLI structure 230 is formed to provide a vertical connection between the upper source/drain epitaxial structures 176 and the lower source/drain epitaxial structures 174 in the same column. The function of the VLI structure 230 is to reduce the parasitic resistance and capacitance that can occur when the source and drain regions are connected horizontally using metal lines. The VLI structure 230 provides a shorter and more direct path for the current to flow, which reduces the resistance and improves the performance of the device. In addition to reducing parasitic resistance and capacitance, the VLI structure 230 also provides a more compact and efficient design. By connecting the source/drain epitaxial structures vertically, the device can be made smaller, which reduces the overall size and cost of the circuit. In some embodiments, the VLI structure 230 can be interchangeably referred to as metal-like defined (MD) local interconnect (MDLI).

In FIG. 1, the VLI structure 230 is an L-shaped structure. An isolation structure 240 is formed over the VLI structure 230. The VLI structure 230 having L-shaped can reduce the resistance and capacitance of the interconnect, which can improve the performance of the CFET. The L-shape design of the VLI structure 230 allows for a shorter distance between the gate and source/drain regions, which reduces the overall resistance of the interconnect, which in turn improves the speed, power efficiency, and overall performance of the semiconductor device 100a.

The semiconductor device 100a further includes front-side source/drain contacts 260 disposed over the respective upper source/drain epitaxial structures 176. In some embodiments, the front-side source/drain contacts 260 are respectively in contact with top surfaces of the corresponding upper source/drain epitaxial structures 176. One of the front-side source/drain contacts 260 is connected to the VLI structure 230. The semiconductor device 100a further includes backside source/drain contacts 280 disposed under the lower source/drain epitaxial structure 174. In some embodiments, the backside source/drain contacts 280 are respectively in contact with bottom surfaces of the corresponding lower source/drain epitaxial structures 174. One of the backside source/drain contacts 280 is connected to the VLI structure 230.

Optionally, one of the front-side source/drain contacts 260 is in contact with the isolation structure 240. The semiconductor device 100a further includes at least one source/drain via 292 and conductive lines 294 over the front-side source/drain contacts 260. The front-side source/drain contact 260 may be electrically connected to at least one of the conductive lines 294 through the source/drain via 292 as shown in FIG. 1.

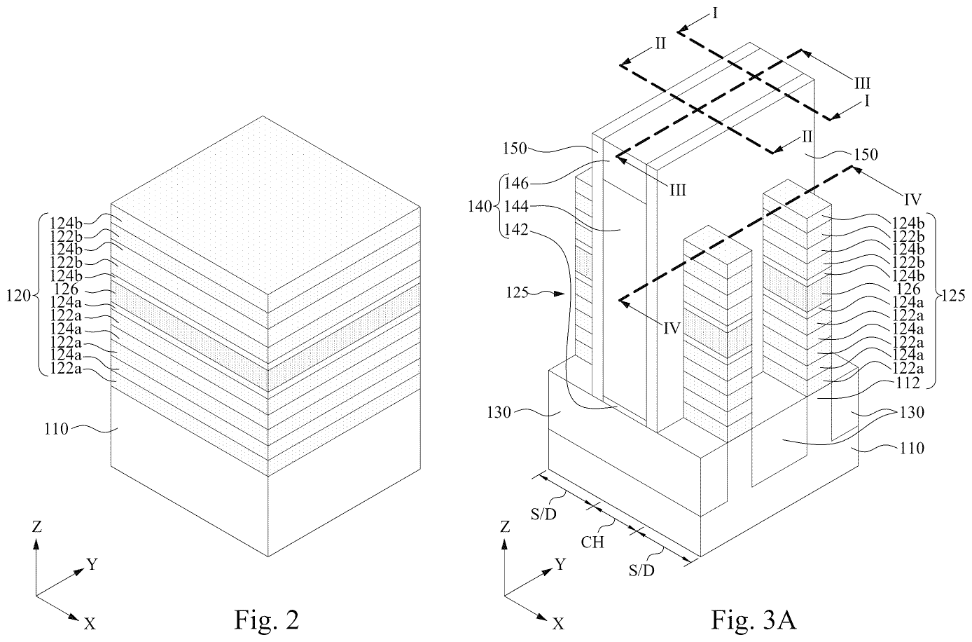

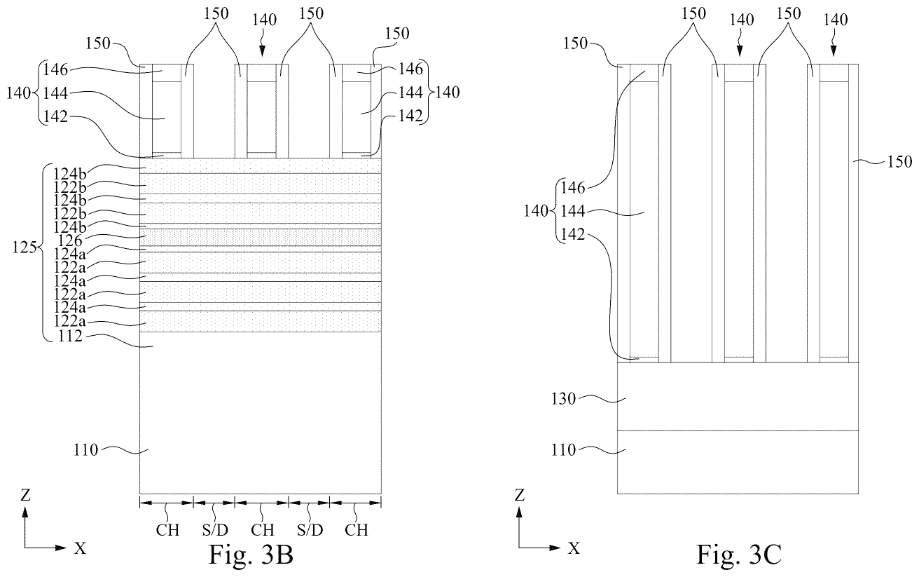

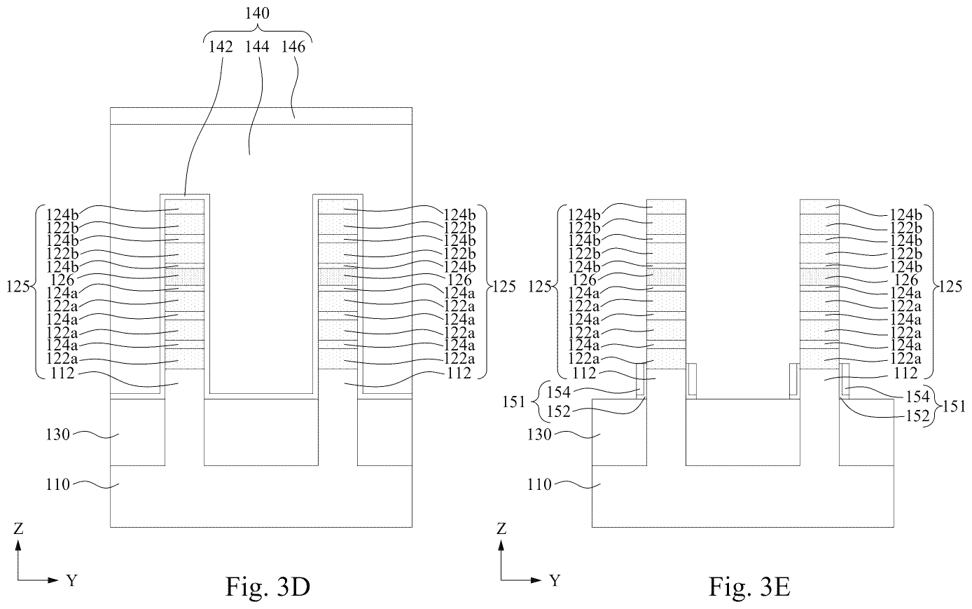

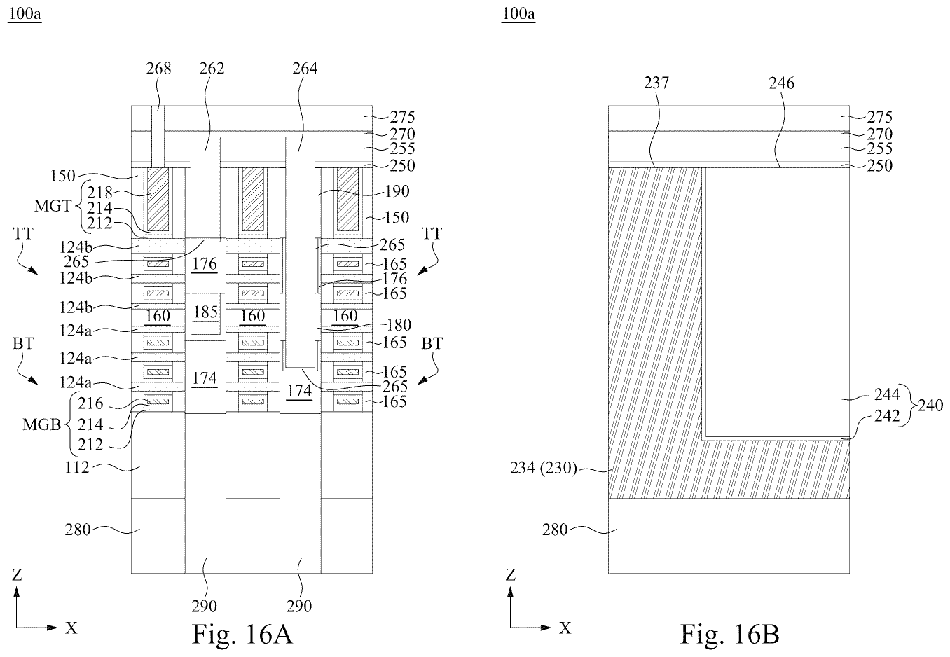

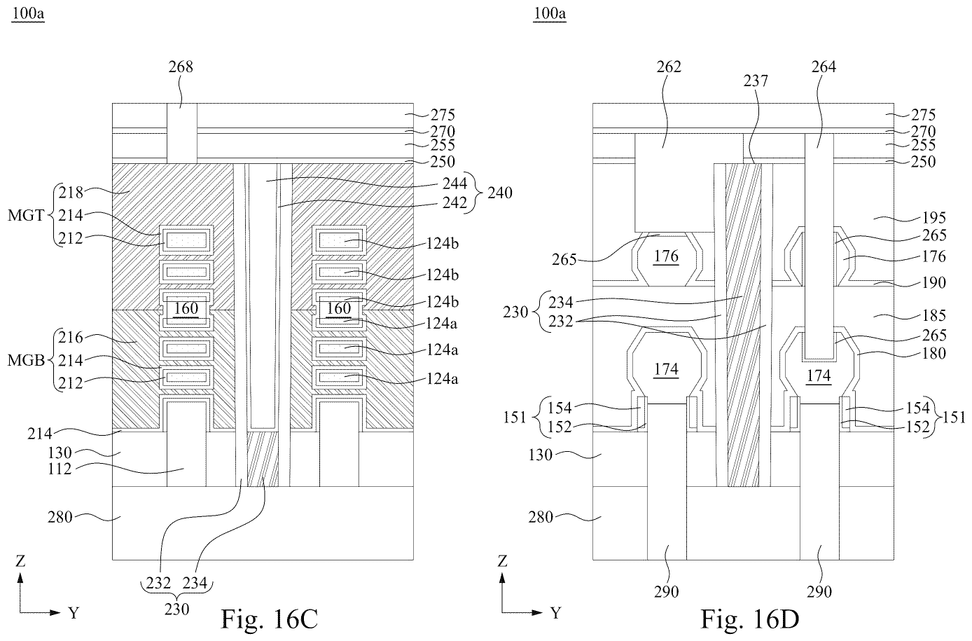

FIGS. 2-16D illustrate perspective views and cross-sectional views of intermediate stages in the formation of the integrated circuit structure (or the semiconductor device) 100a in accordance with some embodiments of the present disclosure. In some embodiments, the semiconductor device 100a in FIGS. 16A-16D is a complementary FET (CFET) device. In addition to the semiconductor device 100a, FIGS. 2 and 3A depict X-axis, Y-axis, and Z-axis directions. FIGS. 3B, 4A, 5A, 6A, 7A, 8A, 9A, 10A, 11A, 12A, 13A, 14A, 15A, and 16A are cross-sectional views of some embodiments of the semiconductor device 100a at intermediate stages along a first cut (e.g., cut I-I in FIG. 3A). FIGS. 3C, 4B, 5B, 6B, 7B, 8B, 9B, 10B, 11B, 12B, 13B, 14B, 15B, 15E, and 16B are cross-sectional views of some embodiments of the semiconductor device 100a at intermediate stages along a second cut (e.g., cut II-II in FIG. 3A). FIGS. 3D, 4C, 5C, 6C, 7C, 8C, 9C, 10C, 11C, 12C, 13C, 14C, 15C, and 16C are cross-sectional views of some embodiments of the semiconductor device 100a at intermediate stages along a third cut (e.g., cut III-III in FIG. 3A). FIGS. 3E, 4D, 5D, 6D, 7D, 8D, 9D, 10D, 11D, 12D, 13D, 14D, 15D, and 16D are cross-sectional views of some embodiments of the semiconductor device 100a at intermediate stages along a fourth cut (e.g., cut IV-IV in FIG. 3A). The formed devices include p-type transistors (such as p-type GAA FETs) and n-type transistors (such as n-type GAA FETs) in accordance with some exemplary embodiments. Throughout the various views and illustrative embodiments, like reference numbers are used to designate like elements. It is understood that additional operations can be provided before, during, and after the processes shown by FIGS. 2-16D, and some of the operations described below can be replaced or eliminated, for additional embodiments of the method. The order of the operations/processes may be interchangeable.

Referring to FIG. 2, a semiconductor stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or combinations thereof) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method.

The semiconductor stack 120 includes semiconductor layers 122a and 122b of a first composition interposed by semiconductor layers 124a and 124b of a second composition arranged in a stacking direction (Z-axis in this case). The semiconductor stack 120 further includes a semiconductor layer 126 between the topmost semiconductor layer 124a and the bottommost semiconductor layer 124b of a third composition. The first, second, and third compositions are different. In some embodiments, the semiconductor layers 122a, 122b, and 126 are SiGe and the semiconductor layers 124a and 124b are silicon (Si). Further, the germanium concentration of the semiconductor layer 126 is higher than the germanium concentration of the semiconductor layer 122a and 122b. However, other embodiments are possible including those that provide for a first composition, a second composition, and a third composition having different etch selectivity.

The semiconductor layers 124a and 124b or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the semiconductor layers 124a and 124b to define a channel or channels of a device is further discussed below.

In FIG. 2, the semiconductor layers 124b are disposed above the semiconductor layers 124a. It is noted that three layers of the semiconductor layers 124a and three layers of the semiconductor layers 124b are arranged as illustrated in FIG. 2, which is for illustrative purposes only and not intended to be limiting beyond what is specifically recited in the claims. It can be appreciated that any number of semiconductor layers can be formed in the semiconductor stack 120; the number of layers depending on the desired number of channels regions for the transistor. In some embodiments, the number of each of the semiconductor layers 124 a and 124 b is between 2 and 10.

As described in more detail below, the semiconductor layers 124a and 124b may serve as channel region(s) for a subsequently-formed semiconductor device and the thickness is chosen based on device performance considerations. The semiconductor layers 122a and 122b in channel region(s) may eventually be removed and serve to define a vertical distance between adjacent channel region(s) for a subsequently-formed multi-gate device and the thickness is chosen based on device performance considerations. Accordingly, the semiconductor layers 122a and 122b may also be referred to as sacrificial layers, and the semiconductor layers 124a and 124b may also be referred to as channel structures.

By way of example, epitaxial growth of the layers of the semiconductor stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the semiconductor layers 124a and 124b include the same material as the substrate 110. In some embodiments, the semiconductor layers 122a, 122b, 124a, 124b, and 126 include a different material than the substrate 110. As stated above, in at least some examples, the semiconductor layers 122a, 122b, and 126 include an epitaxially grown silicon germanium (SiGe) layer and the semiconductor layers 124a and 124b include an epitaxially grown silicon (Si) layer. Alternatively, in some embodiments, either of the semiconductor layers 122a, 122b, 124a, 124b, and 126 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the semiconductor layers 122a, 122b, 124a, 124b, and 126 may be chosen based on providing differing oxidation and/or etching selectivity properties.

Reference is made to FIGS. 3A-3E, where FIG. 3B is a cross-sectional view taken along line I-I of FIG. 3A, FIG. 3C is a cross-sectional view taken along line II-II of FIG. 3A, FIG. 3D is a cross-sectional view taken along line III-III of FIG. 3A, and FIG. 3E is a cross-sectional view taken along line IV-IV of FIG. 3A. Fin structures 125 extending from the substrate 110 are formed. In various embodiments, the fin structures 125 each includes a protruding portion 112 formed from the substrate 110 and portions of each of the semiconductor layers of the semiconductor stack including semiconductor layers 122a-122b, 124a-124b, and 126. The fin structures 125 may be fabricated using suitable processes including double-patterning or multi-patterning processes.

Next, isolation structures 130 are formed to surround the fin structures 125. The isolation structures 130 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 130 may also include a dielectric material over the liner oxide, and the dielectric material may be formed using flowable chemical vapor deposition (FCVD), spin-on coating, or the like.

The isolation structures 130 are then planarized, and the top surfaces of the fin structures 125 are exposed. Subsequently, the isolation structures 130 are recessed, so that the top portions of the fin structures 125 protrude higher than the top surfaces of the neighboring isolation structures 130. The etching may be performed using a dry etching process or a wet etch process.

At least one dummy gate structure 140 is formed over the substrate 110 and across the fin structures 125. It is noted that in the first cut (line I-I) and the second cut (line II-II), three dummy gate structures 140 are illustrated in FIGS. 3B and 3C to clearly show the detail of the semiconductor device 100a. The portions of the fin structures 125 underlying the dummy gate structure 140 may be referred to as channel regions CH. The dummy gate structure 140 may also define source/drain regions S/D of the fin structures 125, for example, the regions of the fin structures 125 adjacent and on opposite sides of the channel regions CH.

Dummy gate formation operation forms a dummy gate dielectric layer, a dummy gate electrode layer and a hard mask which may include multiple layers (e.g., a nitride layer and an oxide layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, a dummy gate structure 140 including a dummy gate dielectric layer 142, a dummy gate electrode layer 144 and a hard mask 146 (e.g., a nitride layer and an oxide layer) is formed.

After the formation of the dummy gate structures 140 is completed, gate spacers 150 are formed on opposite sidewalls of the dummy gate structures 140. For example, a spacer material layer is deposited on the substrate 110. The spacer material layer may be a conformal layer that is subsequently etched back to form gate sidewall spacers. In the illustrated embodiments, a spacer material layer is disposed conformally on top and sidewalls of the dummy gate structures 140. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer 152 and a second spacer layer 154 formed over the first spacer layer 152. It is noted that for clarity, the first spacer layer 152 and the second spacer layer 154 are illustrated in FIG. 3E but not in FIGS. 3A and 3B. By way of example, the spacer material layer may be formed by depositing a dielectric material over the dummy gate structures 140 and the fin structures 125 using suitable deposition processes. An anisotropic etching process is then performed on the deposited spacer material layer to expose portions of the fin structures 125 not covered by the dummy gate structures 140 (e.g., over the source/drain regions S/D of the fin structures 125). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 150, for the sake of simplicity. Further, portions of the spacer material layer on sidewalls of the fin structures 125 may be referred to as fin spacers 151.

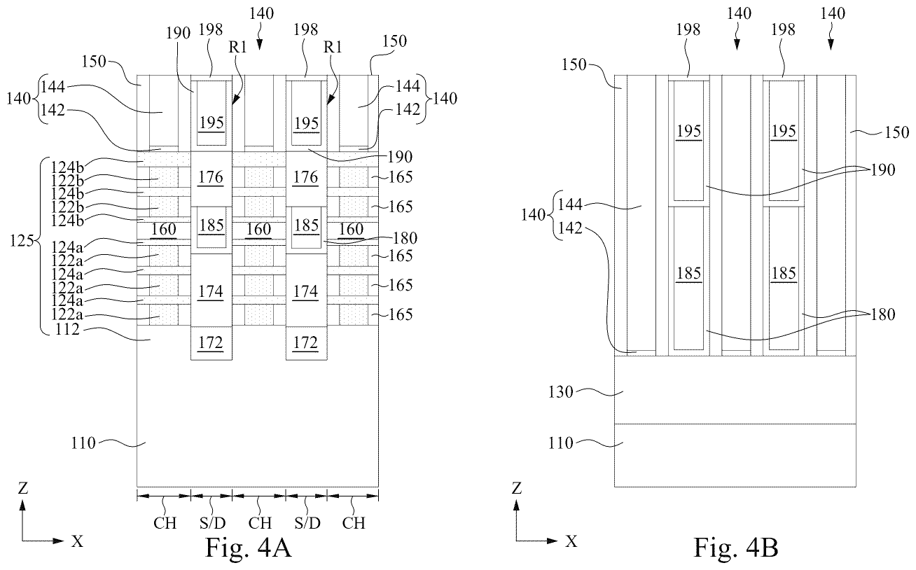

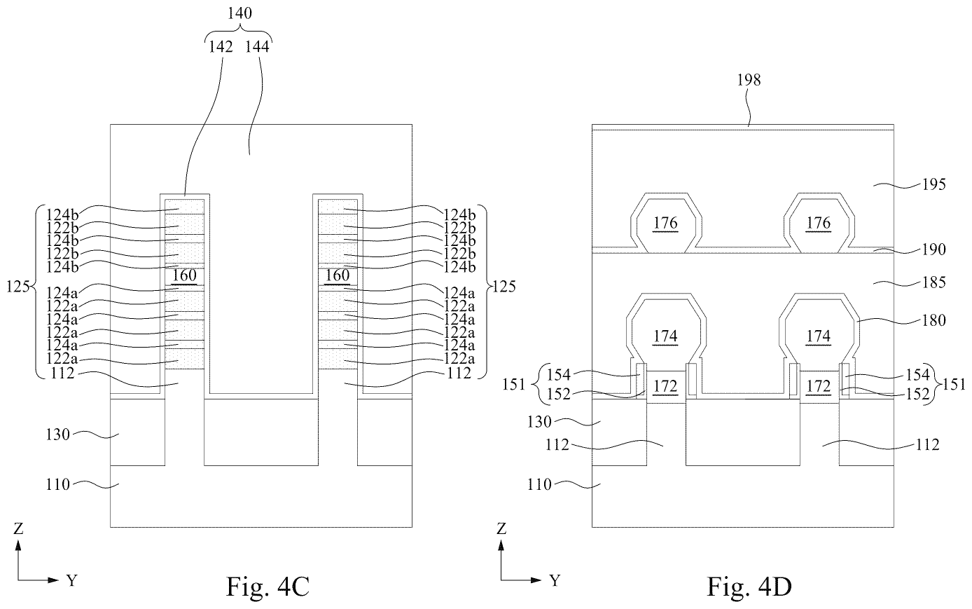

Reference is made to FIGS. 4A-4D. Exposed portions of the fin structures 125 that extend laterally beyond the gate spacers 150 (e.g., in source/drain regions S/D of the fin structures 125) are etched by using, for example, an anisotropic etching process that uses the dummy gate structure 140 and the gate spacers 150 as an etch mask, resulting in recesses R1 into the fin structures 125. After the anisotropic etching, end surfaces of the semiconductor layers 122a-122b, 124a-124b, and 126 and respective outermost sidewalls of the gate spacers 150 are substantially coterminous, due to the anisotropic etching. In some embodiments, the anisotropic etching may be performed by a dry chemical etch with a plasma source and a reaction gas.

The semiconductor layers 126 (see FIGS. 3A-3B and 3D-3E) are removed, resulting in openings between the semiconductor layers 124a and 124b. Subsequently, middle dielectric isolators 160 are filled in the openings, respectively, such that the middle dielectric isolators 160 are between and in contact with the semiconductor layers 124a and 124b. For example, a dielectric material layer is formed to fill the opening. The dielectric material layer may be a low-k dielectric material, such as SiO₂, SiN, SiC, SiON, SiCN, or SiOCN, and may be formed by a suitable deposition method, such as ALD. In some embodiments, the dielectric material layer is intrinsic or un-doped with impurities. The dielectric material layer can be formed using CVD, including LPCVD and PECVD, PVD, ALD, or other suitable processes.

After the deposition of the dielectric material layer, an anisotropic etching process may be performed to remove the dielectric material layer outside the openings, such that portions of the deposited dielectric material layer that fill the openings are left. After the etching process, the remaining portions of the deposited spacer material in the openings are denoted as the middle dielectric isolators 160, for the sake of simplicity. The middle dielectric isolator 160 serves to isolate the semiconductor layers 124a from the semiconductor layers 124b.

The semiconductor layers 122a-122b are then laterally or horizontally recessed by using suitable etch techniques, resulting in lateral recesses each vertically between corresponding semiconductor layers 124a-124b. These operations may be performed by using selective etching processes. In some embodiments, the selective dry etching etches SiGe at a faster etch rate than it etches Si.

Subsequently, inner dielectric spacers 165 are filled in the recesses, respectively. For example, spacer material layers are formed and then trimmed to fill the recesses. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes.

Next, bottom source/drain epitaxial structures 172, lower source/drain epitaxial structures 174, a first contact etch stop layer (CESL) 180, a first interlayer dielectric (ILD) layer 185, upper source/drain epitaxial structures 176, a second CESL 190, and a second ILD layer 195 are sequentially formed in the recesses R1 of the fin structures 125. In some embodiments, semiconductor materials are deposited on the base portions 112 to form the bottom source/drain epitaxial structures 172. The semiconductor materials include a single element semiconductor material, such as germanium (Ge) or silicon (Si), compound semiconductor materials, such as gallium arsenide (GaAs) or aluminum gallium arsenide (AlGaAs), or a semiconductor alloy, such as silicon germanium (SiGe) or gallium arsenide phosphide (GaAsP). The bottom source/drain epitaxial structures 172 have suitable crystallographic orientations (e.g., a (100), (110), or (111) crystallographic orientation). The epitaxial processes include CVD deposition techniques (e.g., vapor-phase epitaxy (VPE) and/or ultra-high vacuum CVD (UHV-CVD)), molecular beam epitaxy, and/or other suitable processes. In some embodiments, the bottom source/drain epitaxial structures 172 are intrinsic. That is, the bottom source/drain epitaxial structures 172 are undoped. The undoped bottom source/drain epitaxial structures 172 are benefit for reducing current leakage from the lower source/drain epitaxial structures 174 to the substrate 110. The bottom source/drain epitaxial structures 172 are spaced apart from the bottommost semiconductor layers 124a.

The lower source/drain epitaxial structures 174 are on the bottom source/drain epitaxial structures 172, respectively. Specifically, the lower source/drain epitaxial structures 174 are on opposite sides and connected to the semiconductor layers 124a and spaced apart from the semiconductor layers 124b. The upper source/drain epitaxial structures 176 are on opposite sides and connected to the semiconductor layers 124b and spaced apart from the semiconductor layers 124a. The lower source/drain epitaxial structures 174 and the upper source/drain epitaxial structures 176 may be formed by performing an epitaxial growth process that provides an epitaxial material on the fin structures 125. In some embodiments, the lattice constants of the lower source/drain epitaxial structures 174 are different from the lattice constant of the semiconductor layers 124a, so that the semiconductor layers 124a can be strained or stressed by the lower source/drain epitaxial structures 174 to improve carrier mobility of the semiconductor device and enhance the device performance. Similarly, the lattice constants of the upper source/drain epitaxial structures 176 are different from the lattice constant of the semiconductor layers 124b. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor layers 124a or 124b.

In some embodiments, the lower source/drain epitaxial structures 174 and the upper source/drain epitaxial structures 176 may include Ge, Si, GaAs, AlGaAs, SiGe, GaAsP, SiP, or other suitable material. The lower source/drain epitaxial structures 174 and the upper source/drain epitaxial structures 176 may be in-situ doped during the epitaxial process by introducing doping species including: p-type dopants, such as boron or BF₂; n-type dopants, such as phosphorus or arsenic; and/or other suitable dopants including combinations thereof. If the lower source/drain epitaxial structures 174 and/or the upper source/drain epitaxial structures 176 are not in-situ doped, an implantation process (i.e., a junction implant process) is performed to dope the lower source/drain epitaxial structures 174 and/or the upper source/drain epitaxial structures 176.

The first CESL 180 is formed on the substrate 110 and covers the bottom source/drain epitaxial structures 172 and the lower source/drain epitaxial structures 174. The second CESL 190 covers the upper source/drain epitaxial structures 176. In some examples, the first CESL 180 and the second CESL 190 include a silicon nitride layer, silicon oxide layer, a silicon oxynitride layer, and/or other suitable materials. The first CESL 180 and the second CESL 190 may be formed by plasma-enhanced chemical vapor deposition (PECVD) process and/or other suitable deposition or oxidation processes.

The first ILD layer 185 is formed over the first CESL 180, and the second ILD layer 195 is formed over the second CESL 190. In some embodiments, the first ILD layer 185 and the second ILD layer 195 include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the first CESL 180. The first ILD layer 185 and the second ILD layer 195 may be deposited by a PECVD process or other suitable deposition technique.

In some examples, after depositing the second ILD layer 195, a planarization process may be performed to remove excessive materials of the second ILD layer 195. For example, a planarization process includes a chemical mechanical planarization (CMP) process which removes portions of the second ILD layer 195 and the second CESL 190 overlying the dummy gate structures 140 and planarizes a top surface of the semiconductor device 100a. In some embodiments, the CMP process also removes hard masks 146 (as shown in FIGS. 3A-3E) and exposes the dummy gate electrode layers 144.

After the CMP process, an etching back process is optionally performed to etch back the second ILD layer 195, resulting in recesses over the etched-back second ILD layer 195. In some embodiments, because the materials of the second ILD layer 195 have a different etch selectivity than the gate spacers 150, the dummy gate electrode layer 144, and the second CESL 190, a selective etching process may be performed to etch back the second ILD layer 195 to lower the second ILD layer 195. As a result, the top surface of the second ILD layer 195 may be at a lower level than the top surfaces of the gate spacers 150 and the second CESL 190.

Subsequently, a dielectric cap layer is deposited over the substrate 110 until the recesses are overfilled. The dielectric cap layer includes SiNₓ, AlₓO_{y}, AlON, SiOₓC_{y}, SiCₓN_{y}, boron nitride (BN), boron carbonitride (BNC), combinations thereof or the like, and is formed by a suitable deposition technique such as CVD, plasma-enhanced CVD (PECVD), ALD, remote plasma ALD (RPALD), plasma-enhanced ALD (PEALD), combinations thereof or the like. A CMP process is then performed to remove the cap layer outside the recess, leaving portions of the dielectric cap layer in the recess to serve as dielectric caps 198. The dielectric caps 198 are in direct contact with the second ILD layer 195 and the second CESL 190. In some embodiments, the formation of the dielectric caps 198 is omitted.

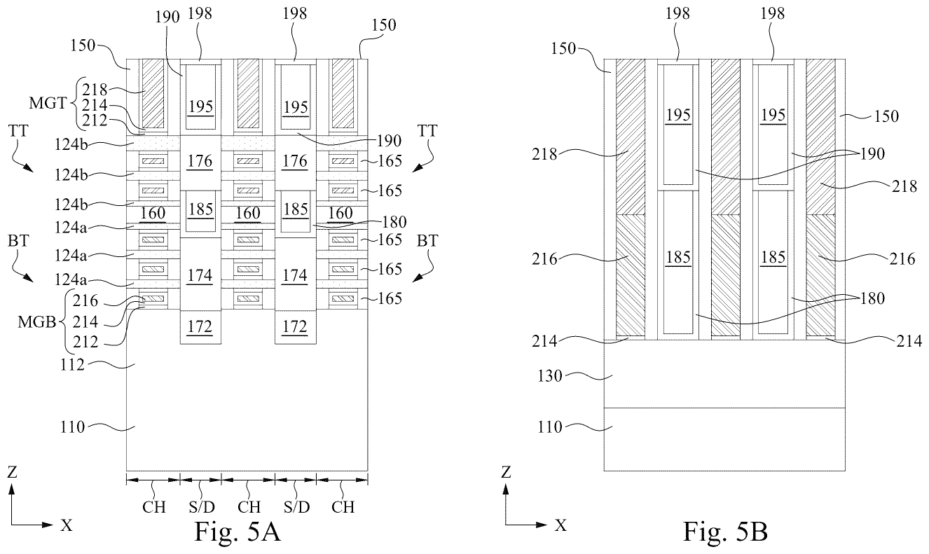

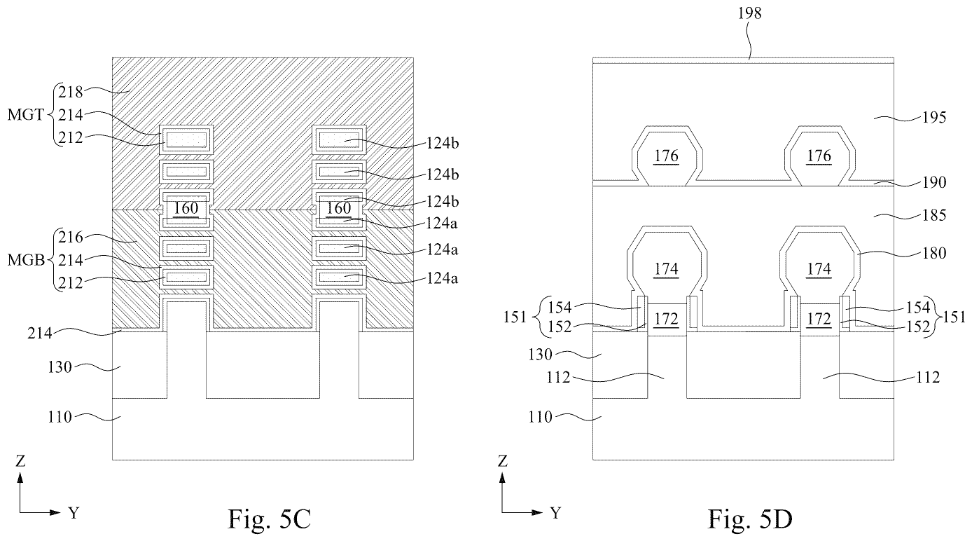

Reference is made to FIGS. 5A-5D. Thereafter, a gate replacement process is performed. Specifically, the dummy gate electrode layer 144 and the dummy gate dielectric layer 142 are removed, and then the semiconductor layers (i.e., sacrificial layers) 122a and 122b are removed. In some embodiments, the dummy gate electrode layers 144 and the dummy gate dielectric layer 142 are removed by using a selective etching process (e.g., selective dry etching, selective wet etching, or combinations thereof) that etches the materials in dummy gate electrode layers 144 and the dummy gate dielectric layer 142 at a faster etch rate than it etches other materials (e.g., the gate spacers 150 and/or the dielectric caps 198), thus resulting in gate trenches between the gate spacers 150, with the semiconductor layers 122a and 122b exposed in the gate trenches. Subsequently, the semiconductor layers 122a and 122b in the gate trenches are removed by using another selective etching process that etches the semiconductor layers 122a and 122b at a faster etch rate than it etches the semiconductor layers 124a and 124b, thus forming openings between neighboring semiconductor layers 124a and 124b. In this way, the semiconductor layers 124a and 124b become nanosheets suspended over the substrate 110. This operation is also called a channel release process. In some embodiments, the semiconductor layers 124a and 124b can be interchangeably referred to as nanostructure (nanowires, nanoslabs and nanorings, nanosheet, etc., depending on their geometry). For example, in some other embodiments the semiconductor layers 124a and 124b may be trimmed to have a substantial rounded shape (i.e., cylindrical) due to the selective etching process for completely removing the semiconductor layers 124a and 124b. In that case, the resultant semiconductor layers 124a and 124b can be called nanowires.

In some embodiments, the semiconductor layers 122a and 122b are removed by using a selective dry etching process by using, for example, CF₄ as etching gases. In some embodiments, the semiconductor layers 122a and 122b are SiGe and the semiconductor layers 124a and 124b are silicon allowing for the selective removal of the semiconductor layers 122a and 122b.

Interfacial layers 212 are then formed around the semiconductor layers 124a and 124b. In some embodiments, the interfacial layer 212 may include a dielectric material such as silicon oxide (SiO₂), HfSiO, or silicon oxynitride (SiON). The interfacial layers 212 may be formed by chemical oxidation, thermal oxidation, atomic layer deposition (ALD), chemical vapor deposition (CVD), and/or other suitable method. In some embodiments, when the interfacial layers 212 are formed by oxidation, the interfacial layers 212 are grown on the surfaces of semiconductor materials, such as the semiconductor layers 124a and 124b.

Thereafter, high-k gate dielectric layers 214 are formed to cover the interfacial layers 212. High-k gate dielectrics include dielectric materials having a high dielectric constant, for example, greater than that of thermal silicon oxide (~3.9). The high-k gate dielectric layer 214 of the gate dielectric layer may include hafnium oxide (HfO₂). Alternatively, the high-k gate dielectric layer 214 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO2), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. The high-k gate dielectric layers 214 may be formed by atomic layer deposition (ALD), chemical vapor deposition (CVD), and/or other suitable method.

Next, a work function metal layer 216 is deposited in the gate trenches and fills the gate trenches. The work function metal layer 216 may include work function metals to provide a suitable work function for (metal) gate structures MGB. For a p-type FET, the work function metal layer 216 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. The work function metal layer 216 may be formed by atomic layer deposition (ALD), chemical vapor deposition (CVD), and/or other suitable method. Subsequently, one or more CMP processes are performed to remove excessive gate materials.

After the formation of the work function metal layer 216, the work function metal layer 216 is etched back by using an etching process, and the top portions of the high-k gate dielectric layers 214 are exposed. Subsequently, another work function metal layer 218 is deposited in the gate trenches and over the work function metal layer 216 and fills the gate trenches. For an n-type FET, the work function metal layer 218 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials.

Therefore, the interfacial layers 212, the high-k gate dielectric layers 214, and the work function metal layer 216 form (metal) gate structures MGB, and the interfacial layers 212, the high-k gate dielectric layers 214, and the work function metal layer 218 form (metal) gate structures MGT over the gate structures MGB.

As such, bottom (nanostructure) transistors BT and top (nanostructure) transistors TT are formed. The top transistor TT and the bottom transistor BT in the same column form a CFET. The bottom transistors BT are over the substrate 110 and the isolation structures 130, and the top transistors TT are directly over the bottom transistors BT, respectively. The bottom transistors BT are between the top transistors TT and the isolation structures 130, and the top transistors TT overlap the bottom transistors BT. Each of the bottom transistors BT includes the semiconductor layers (or channel structures or channel layers or channel regions) 124a, the lower source/drain epitaxial structures 174 on opposite sides of the channel structures 124a and connected to the channel structures 124a, and the gate structure MGB wrapping around the channel structures 124a. Each of the top transistors TT includes the e semiconductor layers (or channel structures or channel layers or channel regions) 124b, the upper source/drain epitaxial structures 176 on opposite sides of the channel structures 124b and connected to the channel structures 124b, and the gate structure MGT wrapping around the channel structures 124b.

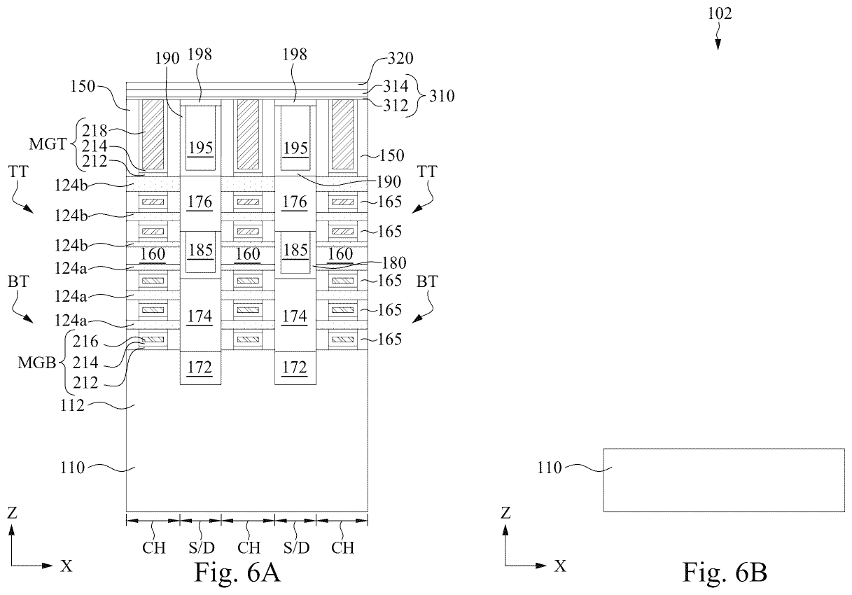

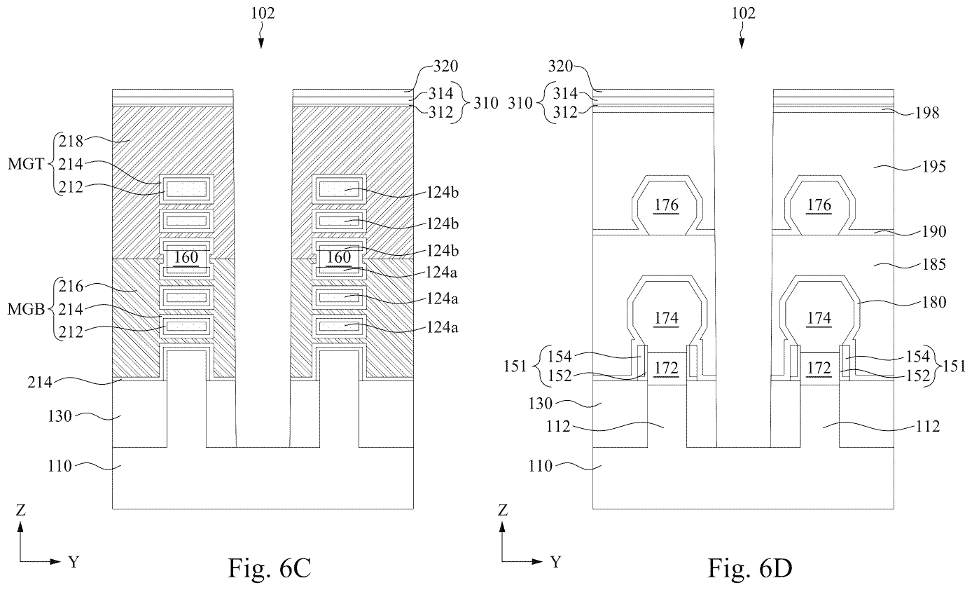

Reference is made to FIGS. 6A-6D. A hard mask structure 310 is deposited over the structure shown in FIGS. 5A-5D. In some embodiments, the hard mask structure 310 includes a first hard mask layer 312 and a second hard mask layer 314 over the first hard mask layer 312. The first hard mask layer 312 and the second hard mask layer 314 may include a silicon-containing material, such as silicon nitride, silicon oxide, amorphous silicon, or other suitable material. The first hard mask layer 312 and the second hard mask layer 314 have different material characterization, such that the first hard mask layer 312 and the second hard mask layer 314 are patterned by different etching processes. The hard mask structure 310 may include a single hard mask layer or multiple hard mask layers.

A photoresist layer 320 is deposited over the hard mask structure 310. The photoresist layer 320 may be formed of a photosensitive material, which includes organic materials, and may be a positive photosensitive material or a negative photosensitive material. Subsequently, the photoresist layer 320, the hard mask structure 310, and the structure under the hard mask structure 310 are sequentially patterned, such that a trench 102 is formed as shown in FIGS. 6B-6D. The trench 102 is formed between the two stacks of the semiconductor layers 124a and 124b. The trench 102 extends through the gate structures MGT and MGB to the top surface of the substrate 110, and some of the gate structures MGT and MGB, the gate spacers 150, the CESL 180, 190 and the ILD 185, 195 are removed. In some embodiments, the trench 102 has high aspect ratio and is tapered toward the substrate 110.

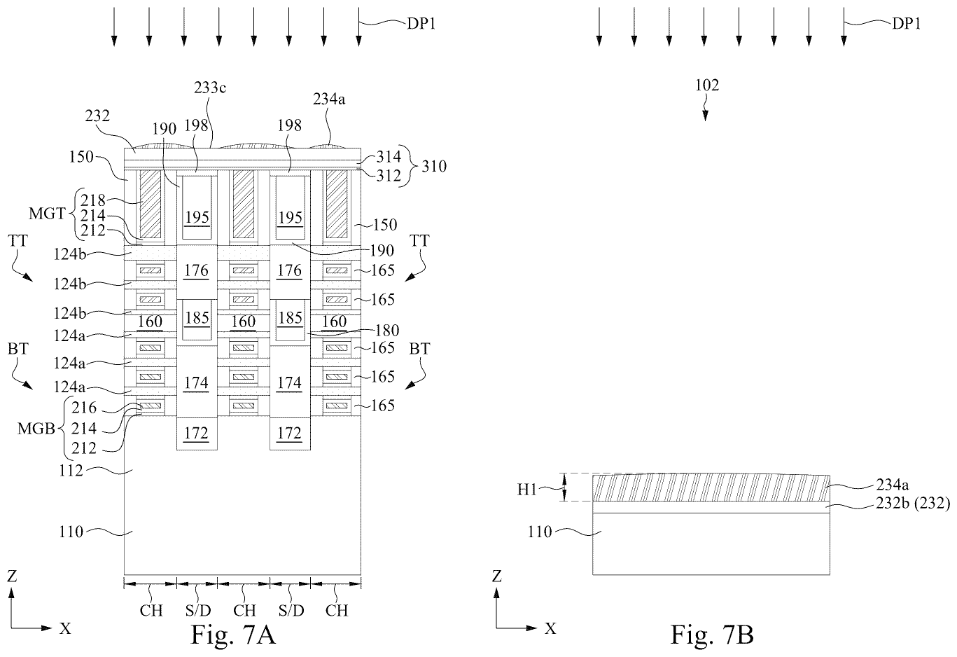

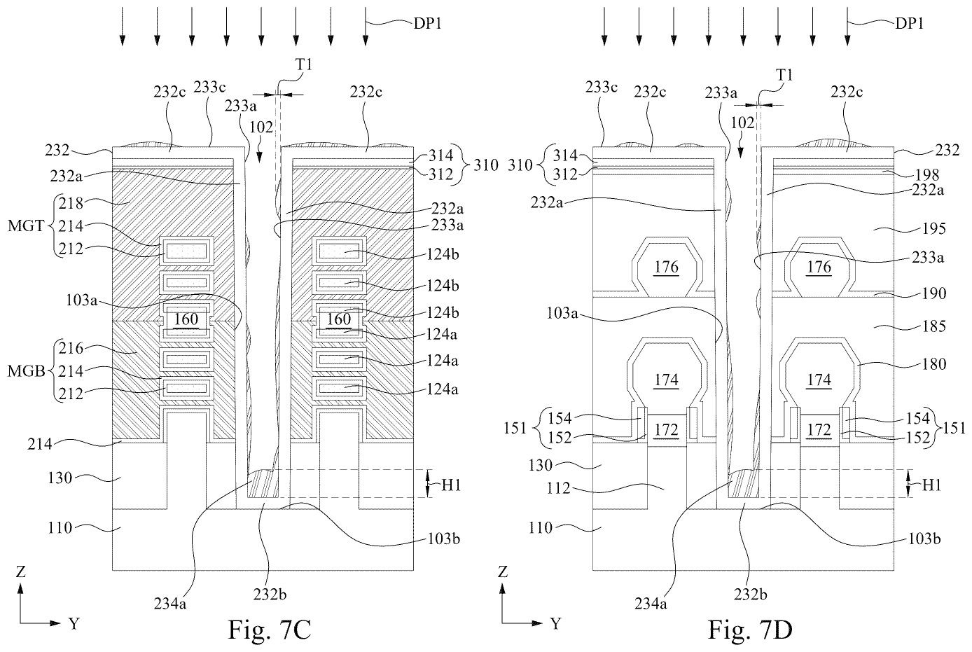

FIGS. 7A-13D illustrate forming a vertical local interconnect (VLI) structure 230 in the trench 102. Reference is made to FIGS. 7A-7D. The photoresist layer 320 in FIGS. 6A-6D is removed. A dielectric liner 232 is then formed to line sidewalls 103a and bottom 103b of the trench 102 and extends through the patterned hard mask structure 310. The dielectric liner 232 is in contact with the patterned hard mask structure 310, the gate structures MGB and MGT, the isolation structures 130, and the substrate 110. The dielectric liner 232 further covers the patterned hard mask structure 310. In some embodiments, the dielectric liner 232 may be an oxygen-free liner. In some embodiments, the dielectric liner 232 may include silicon nitride formed by a deposition process.

Subsequently, a deposition process DP1 is performed to form conductive materials 234a in the trench 102 and over and in contact with the dielectric liner 232. Specifically, conductive materials 234a are deposited by using PVD processes, CVD processes, RPCVD processes, PECVD processes, ALD processes, PEALD processes, electroplating (ECP) processes, electroless plating processes, or the like. The conductive materials 234a may include a low resistivity conductor material, for example, having metal resistivity less than 48 μΩ·cm. In some embodiments, the conductive materials 234a may include ruthenium, tungsten, or the like. The conductive materials 234a are deposited on the sidewall portions 232a and the bottom portion 232b of the dielectric liner 232. Since the trench 102 is tapered toward the substrate 110, the conductive materials 234a are easily to be merged at the bottom of the trench 102. The conductive materials 234a may be deposited slower on the sidewall portions 232a than on the bottom portion 232b of the dielectric liner 232. As shown in FIGS. 7C and 7D, the conductive materials 234a form grains which may not cover the entirety of the inner sidewalls 233a of the sidewall portions 232a. Stated another way, certain areas of the inner sidewalls 233a of the sidewall portions 232a are left exposed by the conductive materials 234a.

The portion of the conductive materials 234a on the bottom portion 232b of the dielectric liner 232 has a height H1 in a range of about 10 nm and about 20 nm. If the height H1 is greater than about 20 nm, the conductive materials 234a may be massively deposited on the sidewall portions 232a and form voids and/or pits therein; if the height H1 is less than about 10 nm, the bottom portion of the conductive materials 234 a may be mostly removed in the following etching process.

Portions of the conductive materials 234a on the sidewall portions 232a of the dielectric liner 232 has a thickness T1 (in the cross-sectional views as shown in FIGS. 7C and 7D) in a range of about 1 nm to about 2 nm. If the thickness T1 is greater than about 2 nm, the conductive materials 234a on the sidewall portions 232a may be mostly merged and thus voids and/or pits may be formed in the conductive materials 234a; if the thickness T1 is less than about 1 nm, the conductive materials 234a on the bottom portion 232b may not reach to the desired height H1.

The dielectric liner 232 further includes top portions 232c over the hard mask material 310 and directly over the gate structures MGB and MGT. The conductive materials 234a are further deposited on the top portions 232c. The amount of the conductive materials 234a on the top portions 232c is less than the amount of the conductive materials 234a on the bottom portion 232b as shown in FIGS. 7C and 7D. The conductive materials 234a further expose top surfaces 233c of the top portions 232c.

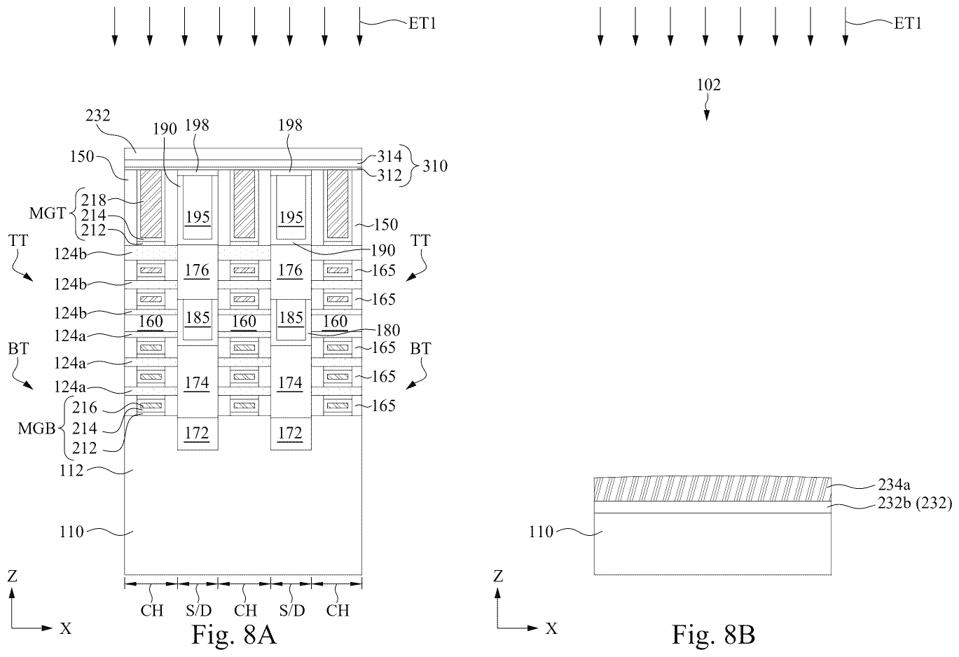

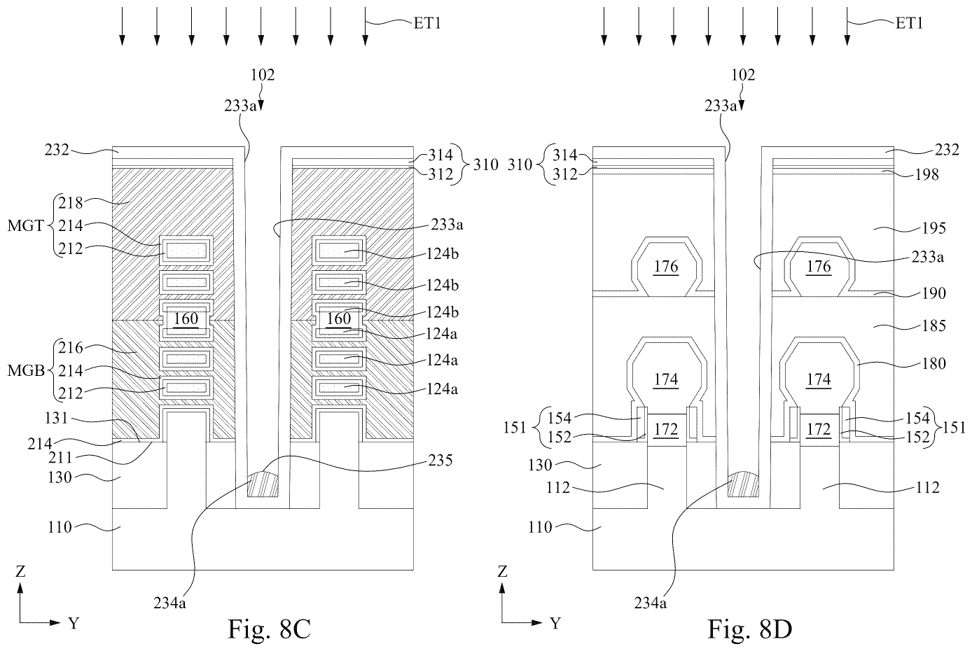

Reference is made to FIGS. 8A-8D. An etching process ET1 is performed to the conductive materials 234a. The etching process ET1 may include a chemical etching method. In accordance with some embodiments of the present disclosure in which the conductive materials 234a are formed of ruthenium, the etching gas may be O₃, a mixing gas including chlorine and O₂, or the like. The etching process ET1 is a selective etching process, which etches conductive materials (e.g., metals) at a rate faster than it etches dielectric materials (e.g., the dielectric liner 232). Therefore, the etching process ET1 etches conductive materials 234a while does not significantly etch the dielectric liner 232. The etching process ET1 is an isotropic etching process. The conductive materials 234a are etched in both of vertical and horizontal directions during the isotropic etching process.

In some embodiments, the etching process ET1 removes the conductive materials 234a to achieve a thickness reduction in a range of about 0.5 nm to about 1.5 nm. Since the amounts of the conductive materials 234a on the sidewall portions 232a and the top portions 232c of the dielectric liner 232 are less than the amount of the conductive materials 234a on the bottom portion 232b of the dielectric liner 232, the parts of the conductive materials 234a on the sidewall portions 232a and the top portions 232c are mostly removed while the parts of the conductive materials 234a on the bottom portion 232b remains as shown in FIGS. 8B-8D. After the etching process ET1, the inner sidewalls 233a of the sidewall portions 232a are mostly free of the conductive materials 234a. Further, after etching process ET1, a top surface 235 of the conductive material 234a remaining in the bottom of the trench 102 is lower than a top surface 131 of the isolation structure 130, lower than a bottom surface 211 of the gate structure MGB, and lower than the lowest channel structures 124a of the bottom transistor BT. In some embodiments, the top surface 235 is convex after the etching process ET1.

In some embodiments, to achieve the desired thickness reduction mentioned above, a time duration of the etching process ET1 is in a range of about 10 seconds to about 1 minute. If the time duration is less than about 10 seconds, the thickness roughness of the remaining conductive materials 234a may be significant; if the time duration is greater than about 1 minutes, the conductive materials 234a may be removed inefficiently.

In some embodiments, in the scenario that the etching gas including O₃, the etching process ET1 may be performed without plasma. However, in the scenario that the etching gas including the mixing gas including chlorine and O₂, a plasma source may be included to active the mixing gas, which means the etching process ET1 is performed with plasma.

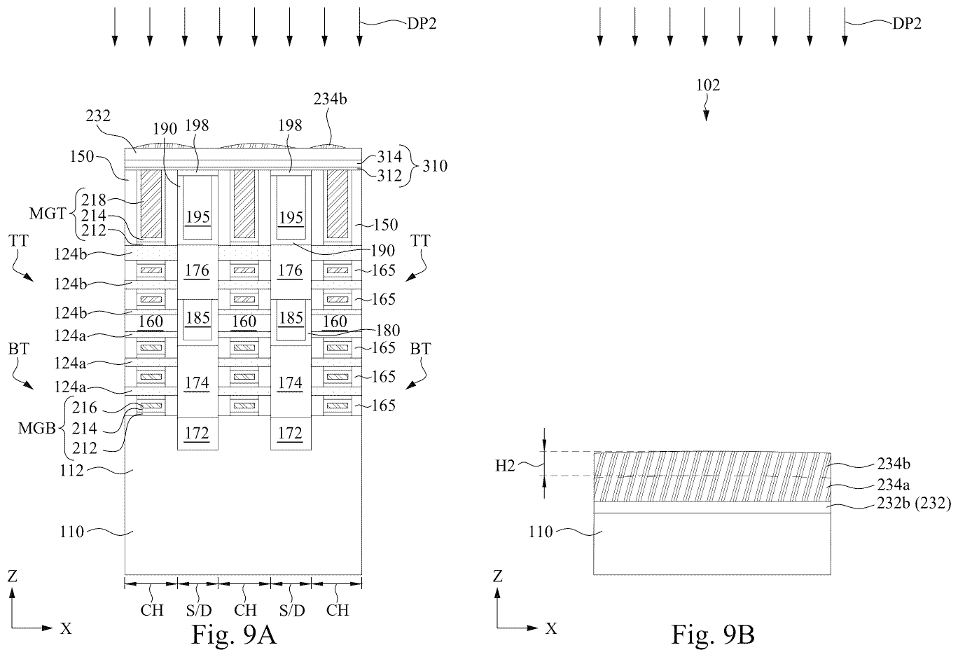

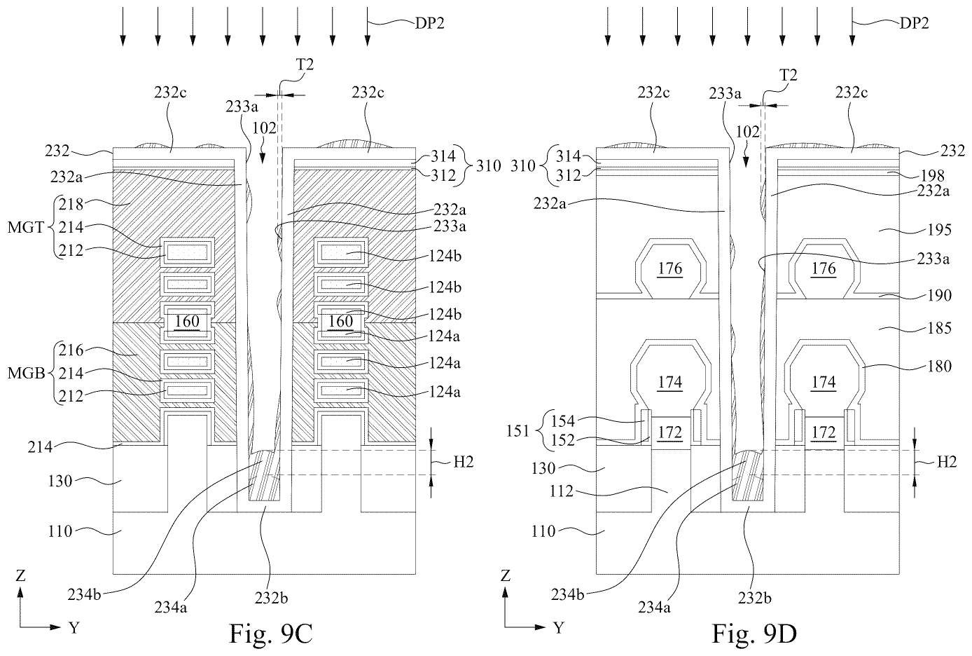

Reference is made to FIGS. 9A-9D. Another deposition process DP2 is performed to form conductive materials 234b in the trench 102 and over and in contact with the dielectric liner 232 and the conductive materials 234a. The details of the deposition process DP2 is similar to the deposition process DP1. The conductive materials 234b and the conductive materials 234a may have the same materials or different materials. In the scenario that the conductive materials 234b and 234a having the same materials, there may be no obvious interface between the conductive materials 234b and 234a. It is noted that the deposition process DP2 (and the deposition process DP1) is a selective deposition process. That is, the conductive materials 234b are deposited on the conductive materials 234a at a rate faster than deposited on the dielectric materials (e.g., the dielectric liner 232). Therefore, the deposition process DP2 can be regarded as a bottom-up deposition process. The conductive materials 234b is deposited slower on the sidewall portions 232a than on the bottom portion 232b of the dielectric liner 232. As shown in FIGS. 9C and 9D, the conductive materials 234b form grains that do not cover the entirety of the inner sidewalls 233a of the sidewall portions 232a. Stated another way, certain areas of the inner sidewalls 233a of the sidewall portions 232a are left exposed by the conductive materials 234b.

The portion of the conductive materials 234b on the bottom portion 232b of the dielectric liner 232 has a height H2 in a range of about 10 nm and about 20 nm. If the height H2 is greater than about 20 nm, the conductive materials 234b may be massively deposited on the sidewall portions 232a and form voids and/or pits therein; if the height H2 is less than about 10 nm, the bottom portion of the conductive materials 234b may be mostly removed in the following etching process.

The conductive materials 234b on the sidewall portions 232a of the dielectric liner 232 has a thickness T2 (in the cross-sectional views as shown in FIGS. 9C and 9D) in a range of about 1 nm to about 2 nm. In the thickness T2 is greater than about 2 nm, the conductive materials 234b on the sidewall portions 232a may be mostly merged and thus voids and/or pits may be formed in the conductive materials 234b; if the thickness T2 is less than about 1 nm, the conductive materials 234b on the bottom portion 232b may not reach to the desired height H2. The conductive materials 234b are further deposited on the top portions 232c. The amount of the conductive materials 234b on the top portions 232c is less than the amount of the conductive materials 234b on the bottom portion 232b as shown in FIGS. 9C and 9D.

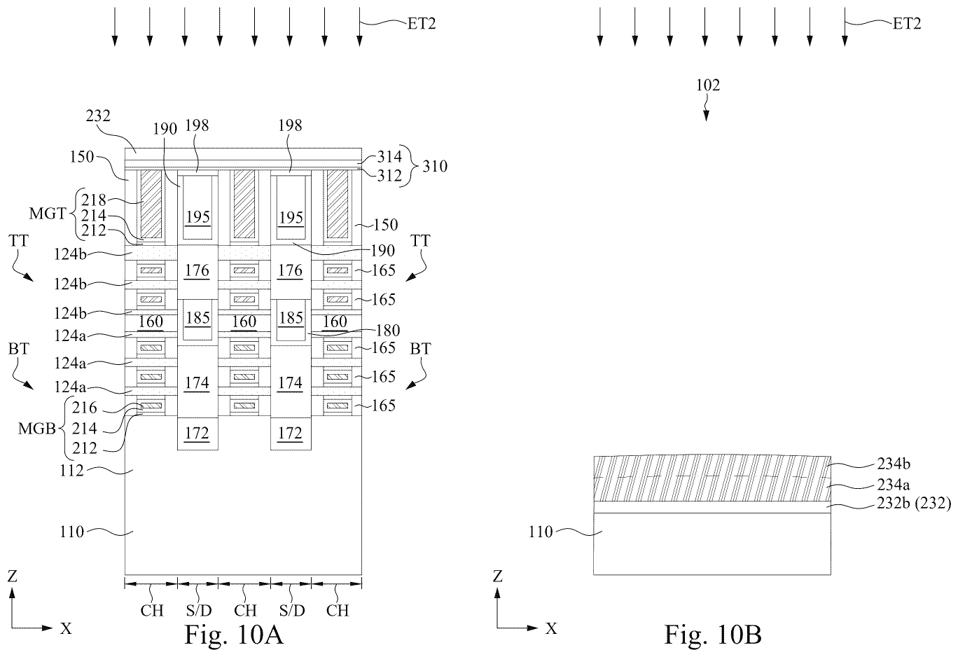

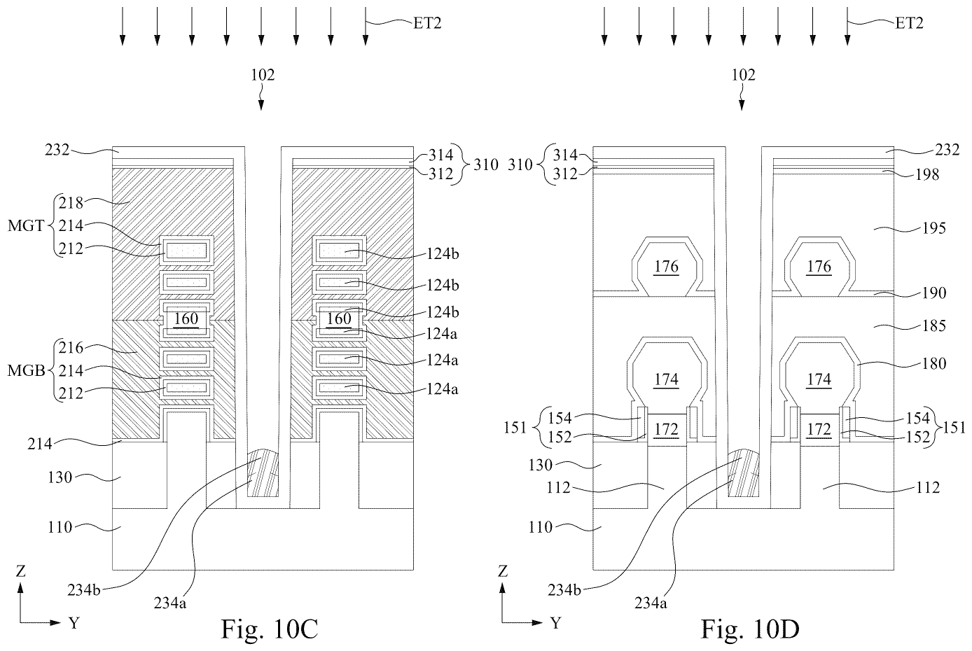

Reference is made to FIGS. 10A-10D. Another etching process ET2 is performed to the conductive materials 234b. The etching process ET2 may be similar to or the same as the etching process ET1. That is, the etching process ET2 may include a chemical etching method and is a selective isotropic etching process. Since the amounts of the conductive materials 234b on the sidewall portions 232a and the top portions 232c of the dielectric liner 232 are less than the amount of the conductive materials 234b on the bottom portion 232b of the dielectric liner 232, the parts of the conductive materials 234b on the sidewall portions 232a and the top portions 232c are mostly removed while the parts of the conductive materials 234b on the bottom portion 232b remains as shown in FIGS. 10B-10D. After the etching process ET2, the inner sidewalls 233a of the sidewall portions 232a are mostly free of the conductive materials 234b.

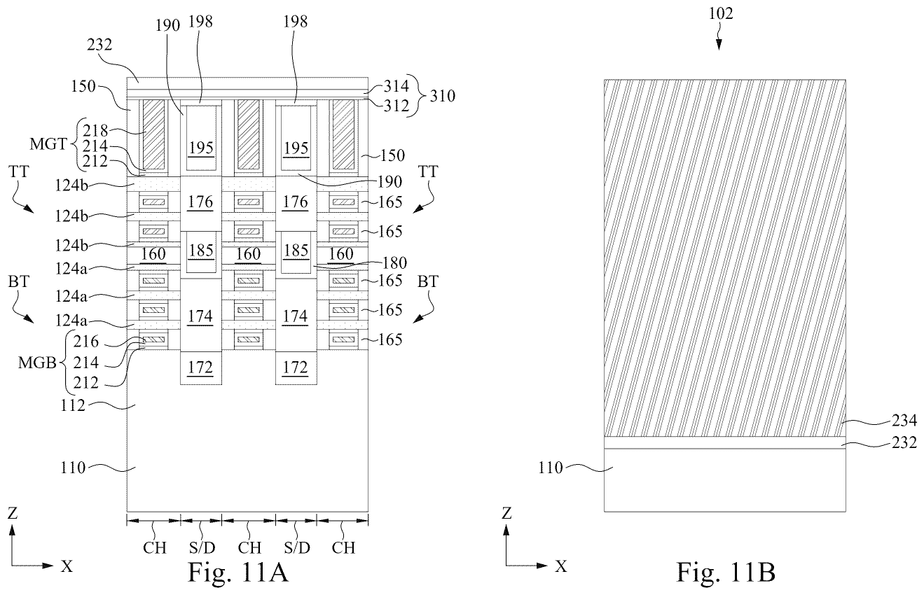

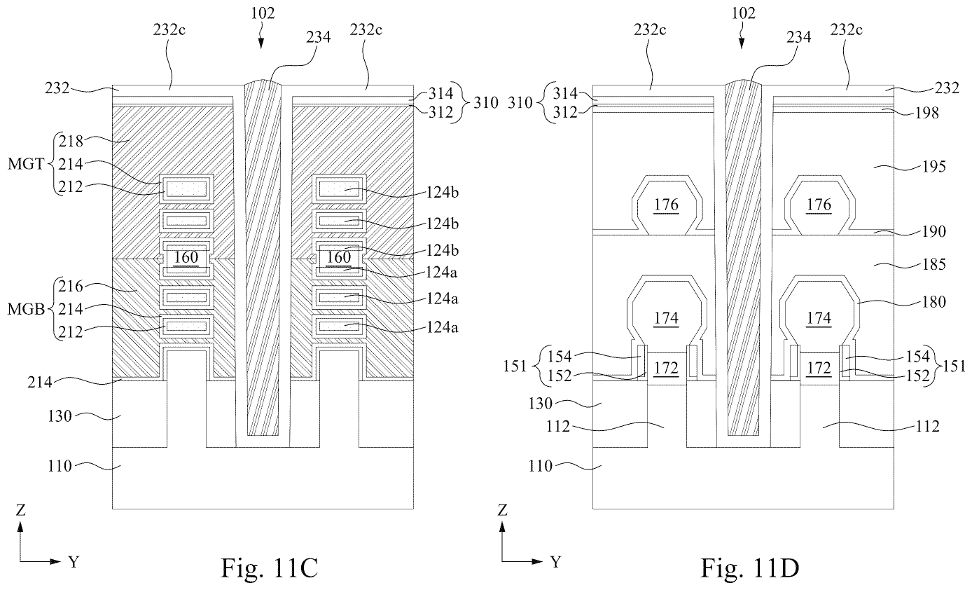

Reference is made to FIGS. 11A-11D. The deposition process (e.g., the deposition processes DP1 and DP2) and the etching process (e.g., the etching processes ET1 and ET2) are repeatedly performed until the trench 102 is filled with the conductive material 234 (which includes the conductive materials 234a and 234b as shown in FIGS. 10B-10D). With such process configuration, the conductive material 234 is free of voids and pits therein. After the final etching process, the conductive material 234 fills the trench 102. Further, portions of the conductive material 234 directly over the hard mask structure 310 are removed. Therefore, the top surface of the top portions 232c of the dielectric liner 232 are substantially free of the conductive material 234.

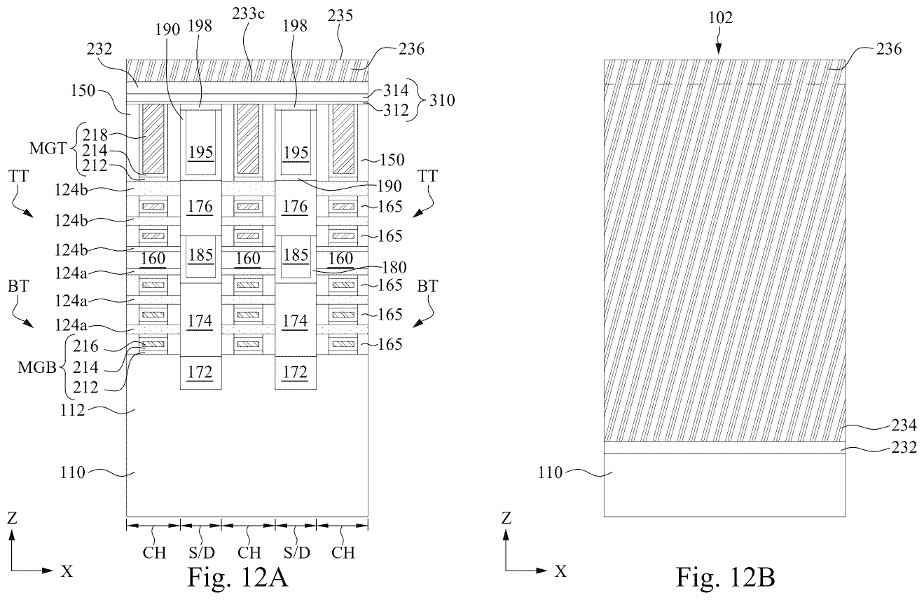

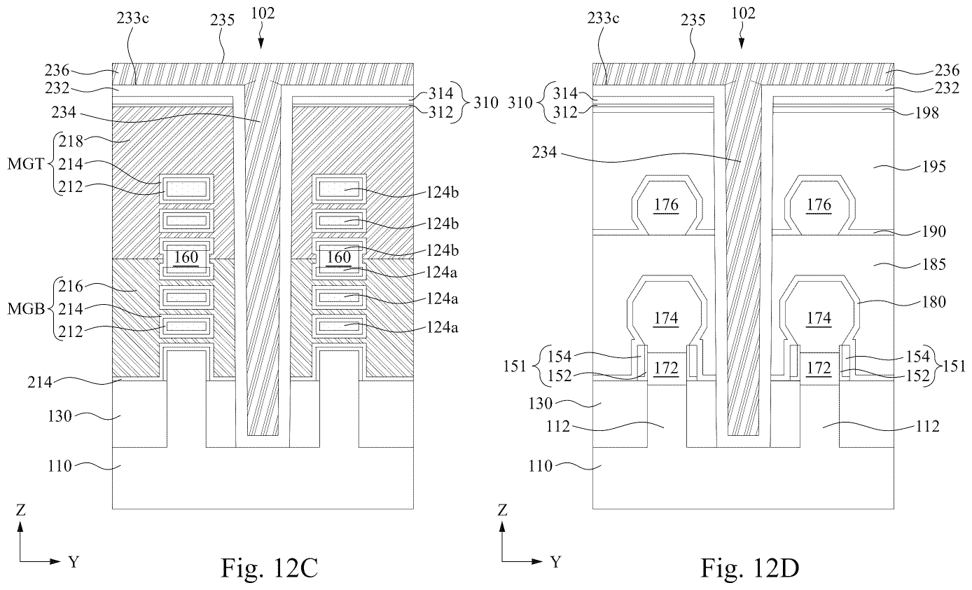

Reference is made to FIGS. 12A-12D. A conductive layer 236 is formed over the conductive material 234, the dielectric liner 232, the gate structures MGB and MGT, and the hard mask structure 310. The conductive layer 236 is deposited by using PVD processes, CVD processes, RPCVD processes, PECVD processes, ALD processes, PEALD processes, electroplating (ECP) processes, electroless plating processes, or the like. The conductive layer 236 may have a material the same or similar to the material of the conductive material 234. As mentioned above, after the etching process shown in FIGS. 11A-11D, the top surface of the hard mask structure 310 is substantially free of the conductive material 234. Therefore, the deposition of the conductive layer 236 is spatially uniform, reducing the thickness variation of the conductive layer 236.

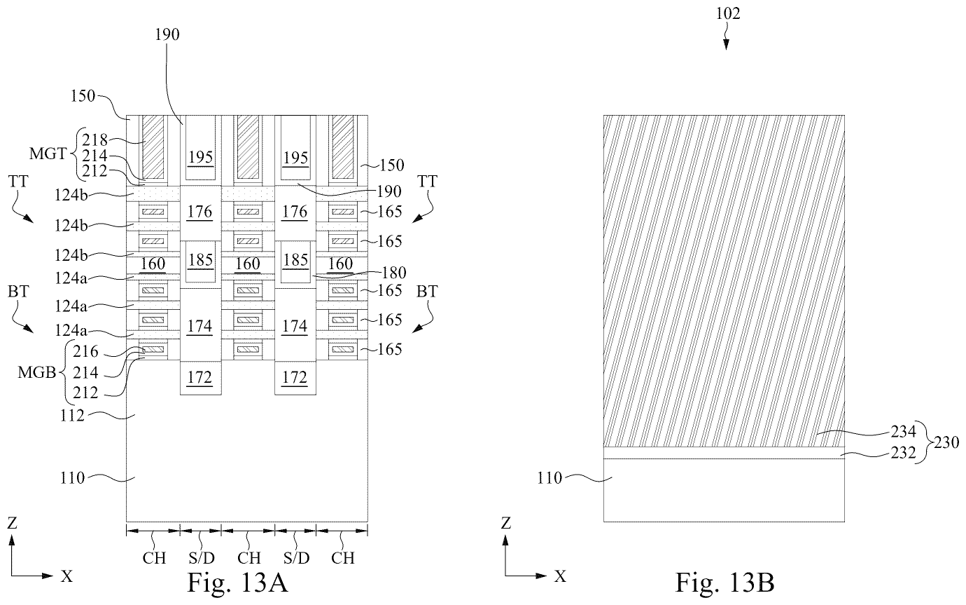

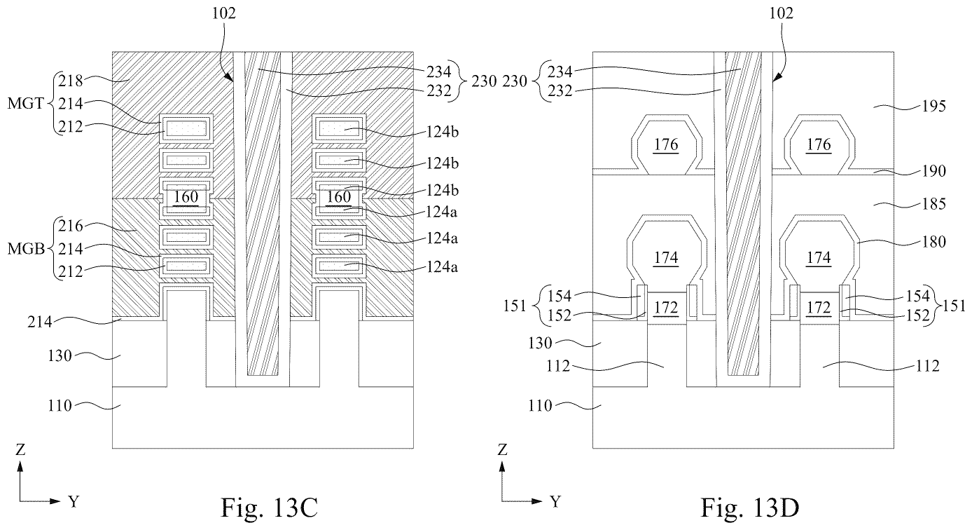

Reference is made to FIGS. 13A-13D. A planarization process is performed to remove excessive materials over the gate structure MGT. For example, a planarization process includes a chemical mechanical planarization (CMP) process which removes parts of the conductive materials 234, the dielectric liner 232, and the hard mask structure 310 outside the trench 102 and overlying the gate structure MGT and planarizes a top surface of the semiconductor device 100a. Therefore, the VLI structure 230 is formed in the trench 102 and includes the dielectric liner 232 and the conductive material 234 having top surfaces level with the gate structure MGT.

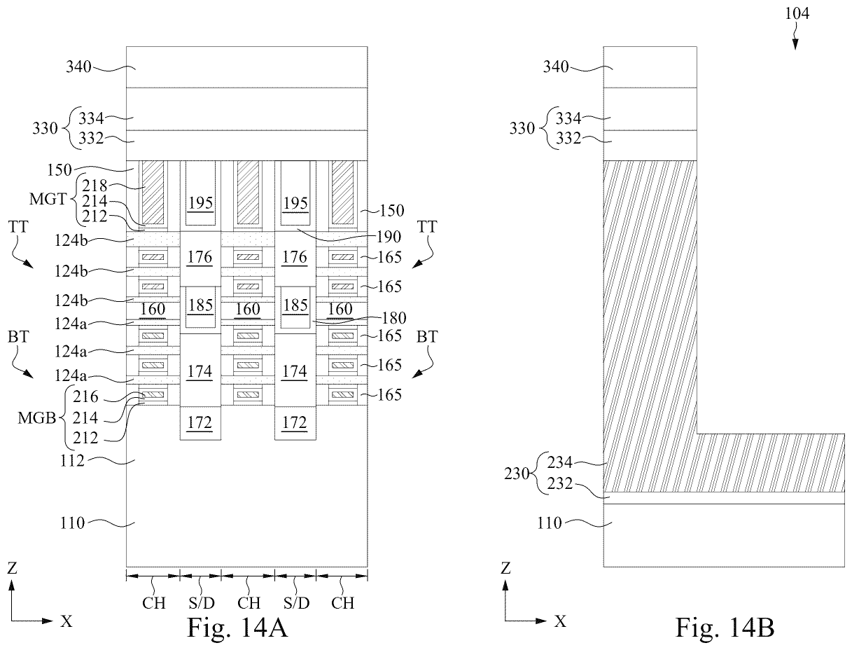

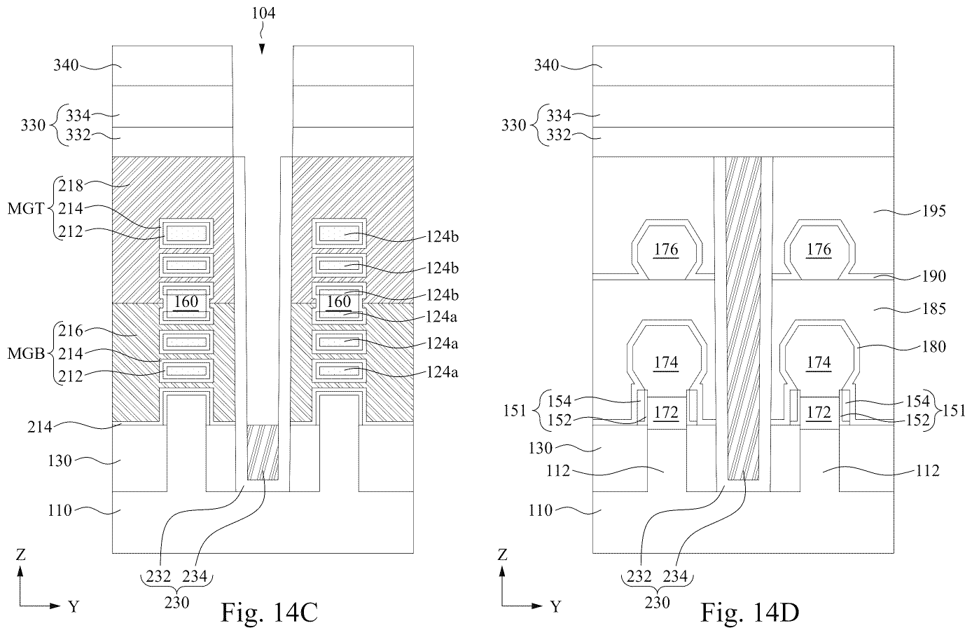

Reference is made to FIGS. 14A-14D. Another hard mask structure 330 is deposited over the structure shown in FIGS. 13A-13D. In some embodiments, the hard mask structure 330 includes a first hard mask layer 332 and a second hard mask layer 334 over the first hard mask layer 332. The first hard mask layer 332 and the second hard mask layer 334 may include a silicon-containing material, such as silicon nitride, silicon oxide, amorphous silicon, or other suitable material. The first hard mask layer 332 and the second hard mask layer 334 have different material characterization, such that the first hard mask layer 332 and the second hard mask layer 334 are patterned by different etching processes. The hard mask structure 330 may include a single hard mask layer or multiple hard mask layers.

Another photoresist layer 340 is deposited over the hard mask structure 330. The photoresist layer 340 may be similar to or the same as the photoresist layer 320 as shown in FIGS. 6A-6D. Subsequently, the photoresist layer 340, the hard mask structure 330, and the structure under the hard mask structure 330 are sequentially patterned, such that a trench 104 is formed as shown in FIGS. 14B-14D. The trench 104 is then formed based on the patterned hard mask structure 330 and recessed from the conductive material 234 of the VLI structure 230, such that the VLI structure 230 can be an L-shaped structure (see FIG. 14B).

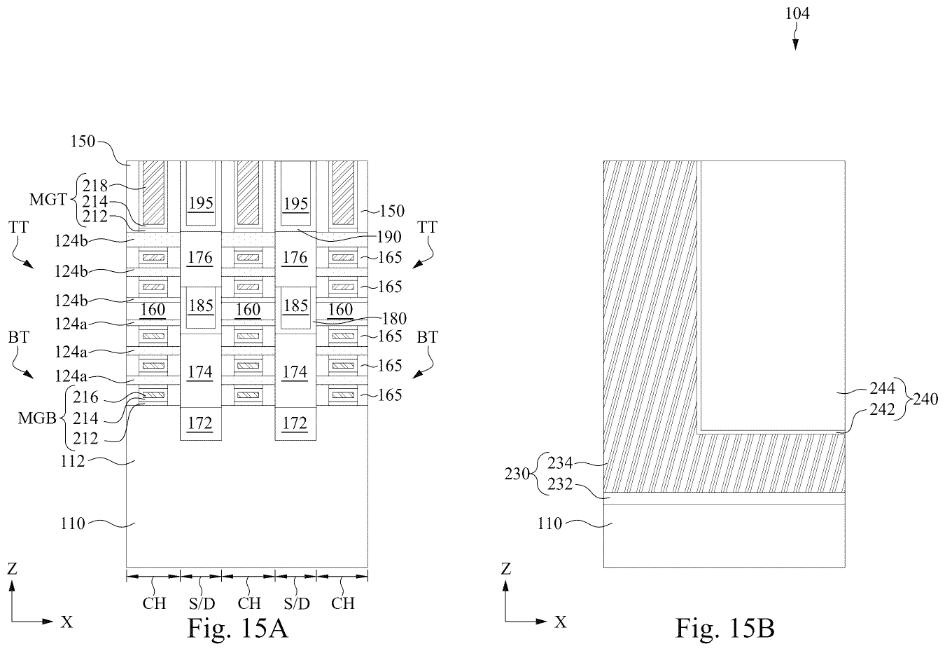

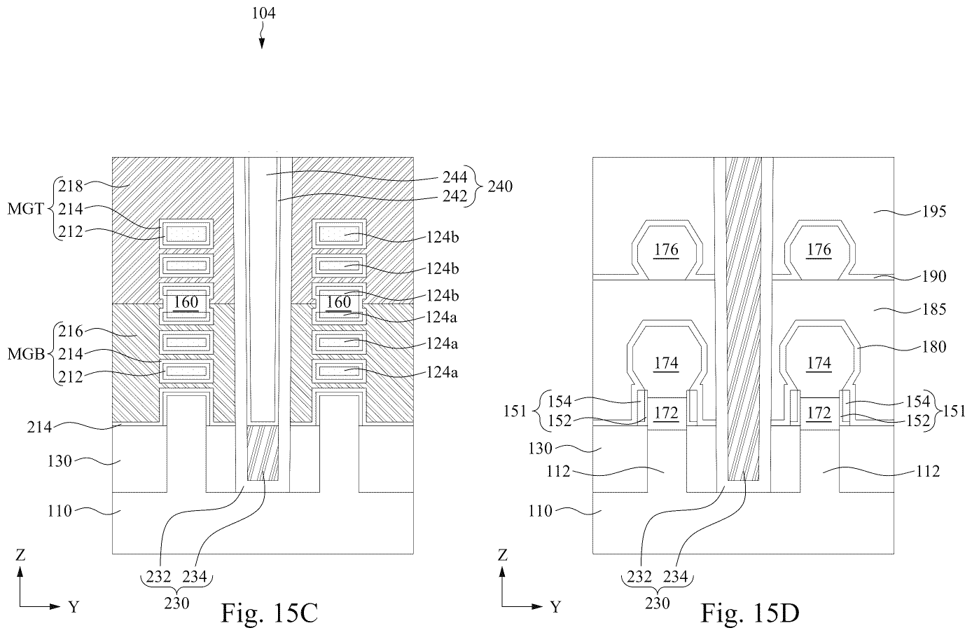

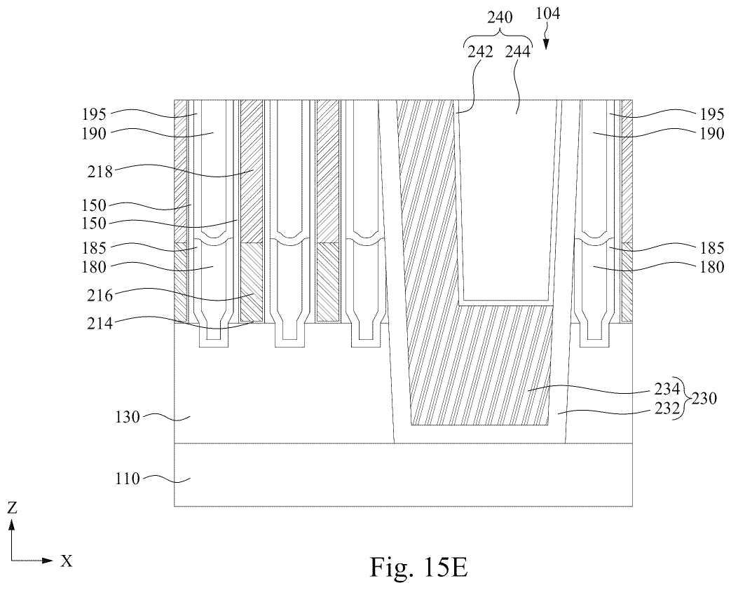

Reference is made to FIGS. 15A-15E, where FIG. 15E is a cross-sectional view taken along line II-II (see FIG. 3A) in accordance with some embodiments of the present disclosure. The photoresist layer 340 in FIGS. 14A-14D is removed. Subsequently, an isolation structure 240 including a dielectric liner 242 and a dielectric material 244 is formed in the trench 104. For example, the dielectric liner 242 is formed to line sidewalls and bottom of the trench 104. The dielectric liner 242 extends from a top surface of the hard mask structure 330 into the trench 104. The dielectric liner 242 may include silicon nitride formed by a deposition process. The dielectric material 244 is then formed over the dielectric liner 242 to fill in the trench 104. In some embodiments, the dielectric material 244 may include oxide material such as silicon oxide formed by deposition and oxidation process. After the dielectric material 244 is formed, one or more planarization process is performed to remove excessive materials over the gate structure MGT. For example, a planarization process includes a chemical mechanical planarization (CMP) process which removes portions of the dielectric material 244, the dielectric liner 242, and the hard mask structure 330 overlying the gate structure MGT and planarizes a top surface of the semiconductor device 100a. Therefore, the isolation structure 240 is formed in the trench 104 and includes the dielectric liner 242 and the dielectric material 244 having top surfaces level with the gate structure MGT.

Reference is made to FIGS. 16A-16D. An etch stop layer 250 and an ILD layer 255 are formed over the structure as shown in FIGS. 15A-15E. Front-side source/drain contacts 262 are then formed through the etch stop layer 250 and the ILD layer 255 to the upper source/drain epitaxial structures 176. Further, front-side source/drain contacts 264 are formed through the etch stop layer 250, the ILD layer 255, the upper source/drain epitaxial structures 176, and the ILD layer 185 to the lower source/drain epitaxial structures 174. The substrate 110 and the bottom portion of the dielectric liner 232 are then removed (e.g., by grinding or CMP) and then replaced with a backside dielectric layer 280, and then backside source/drain contacts 290 are formed through the backside dielectric layer 280 to the lower source/drain epitaxial structures 174. The backside source/drain contacts 290 may be between fin spacers 151. As illustrated in FIG. 16D, a top surface 237 of the conductive material 234 of the VLI structure 230 is in contact with one of the front-side source/drain contacts 262.

As illustrated in FIGS. 16A-16D, the etch stop layer 250 are formed over the second CESL 190, the second ILD 195, the gate spacers 150, the VLI structure 230, and the isolation structure 240. The ILD layer 255 is formed over the etch stop layer 250. Subsequently, openings aligned with the upper source/drain epitaxial structures 176 and the VLI structure 230 are formed and extend through the second ILD layer 195. Metal alloy layers 265 and the front-side source/drain contacts 262 are formed to electrically couple to the upper source/drain epitaxial structures 176, wherein the front-side source/drain contacts 262 are formed in the openings through the ILD layer 255 and the second ILD layer 195 and extend to the metal alloy layers 265 formed in the upper source/drain epitaxial structures 176. Further, the front-side source/drain contacts 264 are formed to electrically couple to the upper source/drain epitaxial structures 176 and the lower source/drain epitaxial structures 174, wherein the front-side source/drain contacts 264 are formed in the openings through the ILD layers 255, 195, and 185 and extend to the metal alloy layers 265 formed in the upper source/drain epitaxial structures 176 and the lower source/drain epitaxial structures 174. In FIGS. 16A-16D, one of the front-side source/drain contacts 262 is also electrically coupled to the VLI structure 230.

After the formation of the front-side source/drain contacts 262 and 264, an etch stop layer 270 and an ILD layer 275 are formed over the ILD layer 255. Openings are then formed in the ILD layers 275, 255 and the etch stop layer 270, 250 to expose the gate structures MGT. Gate vias 268 are formed in the openings through the ILD layers 275, 255 and the etch stop layer 270, 250 to electrically couple to the gate structures MGT.

In FIGS. 16A-16D, the substrate 110 is replaced by the backside dielectric layer 280. The backside source/drain contacts 290 are subsequently formed through the backside dielectric layer 280 and electrically coupled to the lower source/drain epitaxial structures 174 and/or the VLI structure 230. Therefore, one of the upper source/drain epitaxial structures 176 can be electrically connected to one of the lower source/drain epitaxial structures 174 by the VLI structure 230. In some embodiments, the gate vias 268, the front-side source/drain contacts 262, 264, and the backside source/drain contacts 290 may include conductive seed liners and conductive material over the conductive seed liners in the openings.

In FIGS. 16A-16D, the semiconductor device 100a includes the channel structures 124a and 124b, the gate structures MGB and MGT, the lower source/drain epitaxial structures 174, the upper source/drain epitaxial structures 176, and the VLI structure 230. The channel structures 124a and 124b are arrange along the Z direction. Further, in FIG. 16C, the channel structures 124a are also arranged along the Y direction, and the channel structures 124b are also arranged along the Y direction. The gate structures MGB cover the channel structures 124a, and the gate structures MGT cover the channel structures 124b. The gate structures MGB and MGT extend lengthwise along the Y direction. The lower source/drain epitaxial structures 174 are connected to the channel structures 124a and on opposite sides of the gate structures MGB, and the upper source/drain epitaxial structures 176 are connected to the channel structures 124b and on opposite sides of the gate structures MGT. The VLI structure 230 includes the dielectric liner 232 and the conductive material 234. The dielectric liner 232 interfaces the gate structures MGT and MGB as shown in FIG. 16C, and the conductive material 234 is in contact with the dielectric liner 232 and is electrically connected to one of the upper source/drain epitaxial structures 176. As shown in FIG. 16B, the conductive material 234 extends lengthwise along the X direction.

The semiconductor device 100a further includes the isolation structure 240 embedded in the VLI structure 230. In FIG. 16C, the isolation structure 240 is sandwiched between the gate structures MGT and between the gate structures MGB. In FIG. 16B, a portion of the conductive material 234 extends beneath the isolation structure 240. Further, a top surface 246 of the isolation structure 240 is substantially coplanar with the top surface 237 of the interconnect structure 230.

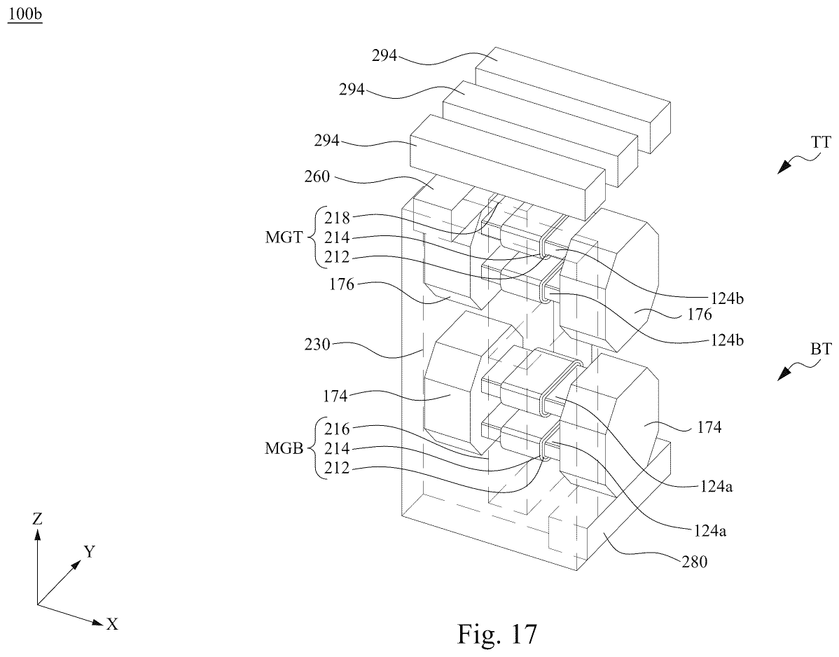

FIG. 17 is a perspective view of an integrated circuit structure (or a semiconductor device) 100b in accordance with some embodiments of the present disclosure. The difference between the semiconductor device 100b and the semiconductor device 100a in FIG. 1 pertains to the shape of the VLI structure 230. In FIG. 17, the VLI structure 230 is a rectangular-shaped structure. Other relevant structural and manufacturing details of the semiconductor device 100b are substantially the same or similar to the semiconductor device 100a of FIG. 1, and, therefore, a description in this regard will not be repeated hereinafter.

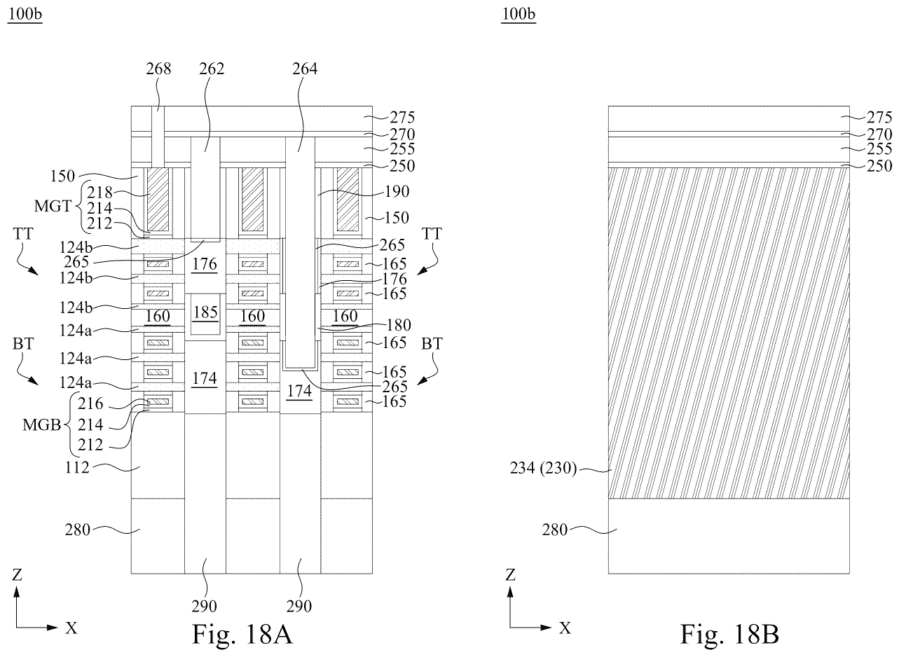

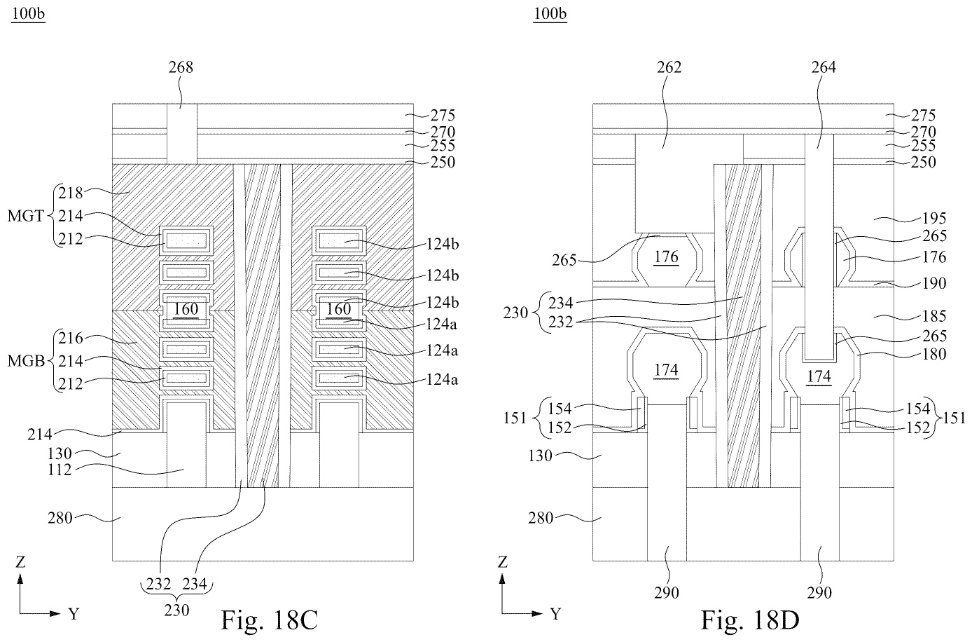

FIGS. 18A-18D are cross-sectional view of the integrated circuit structure (or the semiconductor device) 100b in accordance with some embodiments of the present disclosure. In some embodiments, the processes shown in FIGS. 14A-15E can be omitted. That is, the structure shown in FIGS. 13A-13D skips the processes shown in FIGS. 14A-15E and undergoes the process shown in FIGS. 16A-16D. Therefore, there is no isolation structure 240 formed in the VLI structure 230, such that the VLI structure 230 is a rectangular-shaped structure as shown in FIG. 18B. Other relevant structural and manufacturing details of the semiconductor device 100b are substantially the same or similar to the semiconductor device 100a of FIGS. 16A-16D, and, therefore, a description in this regard will not be repeated hereinafter.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the cyclic (or repeating) deposition and etching processes form a VLI structure without voids and pits therein. Further, the selective deposition process provides a bottom-up deposition for the conductive materials, resulting in an effective deposition for filling the trench of the VLI structure. In addition, the selective etching process prevents the dielectric liner from being damaged during the etching process.

According to some embodiments, a method includes forming a bottom transistor and a top transistor over the bottom transistor. A trench is formed in gate structures of the bottom transistor and the top transistor. A dielectric liner is deposited in the trench. A deposition process is performed to deposit a conductive material in the trench and over the dielectric liner. The conductive material exposes an inner sidewall of the dielectric liner. An etching process is performed to remove parts of the conductive material on sidewall portions of the dielectric liner. A part of the conductive material remains at a bottom of the trench. The deposition process and the etching process are repeatedly performed until the conductive material fills the trench. A part of the dielectric liner and a part of the conductive material outside the trench are removed to form a local interconnect structure including the dielectric liner and the conductive material in the trench.

According to some embodiments, a method includes forming an isolation structure over a substrate. A first transistor and a second transistor are formed over the isolation structure and the substrate. The first transistor is between the second transistor and the isolation structure. A trench is formed in gate structures of the first transistor and the second transistor and in the isolation structure. A dielectric liner is deposited to line sidewalls and a bottom of the trench. A conductive material is deposited in the trench and on the dielectric liner. The conductive material is etched. A top surface of the conductive material is lower than a top surface of the isolation structure after etching the conductive material. The trench is filled with the conductive material. A planarization process is performed to remove the dielectric liner and the conductive material outside the trench.

According to some embodiments, a device includes a first channel structure, a second channel structure, a first gate structure, a second gate structure, a first source/drain structure, a second source/drain structure, and an interconnect structure. The first channel structure and the second channel structure are arranged along a first direction. The first gate structure covers the first channel structure and extends lengthwise along the first direction. The second gate structure covers the second channel structure and extends lengthwise along the first direction. The first source/drain structure and the second source/drain structure are connected to the first channel structure and are on opposite sides of the first gate structure. The interconnect structure includes a dielectric liner and a conductive material. The dielectric liner interfaces the first gate structure and the second gate structure. The conductive material is in contact with the dielectric liner and is electrically connected to the first source/drain structure and extends lengthwise along a second direction different from the first direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a bottom transistor and a top transistor over the bottom transistor;
forming a trench in gate structures of the bottom transistor and the top transistor;
depositing a dielectric liner in the trench;
performing a deposition process to deposit a conductive material in the trench and over the dielectric liner, wherein the conductive material exposes an inner sidewall of the dielectric liner;
performing an etching process to remove parts of the conductive material on sidewall portions of the dielectric liner, wherein a part of the conductive material remains at a bottom of the trench;
repeating performing the deposition process and the etching process until the conductive material fills the trench; and
removing a part of the dielectric liner and a part of the conductive material outside the trench to form a local interconnect structure comprising the dielectric liner and the conductive material in the trench.

2. The method of claim 1, wherein a portion of the conductive material on the sidewall portion of the dielectric liner has a thickness in a range of about 1 nm to about 2 nm.

3. The method of claim 1, wherein a portion of the conductive material on a bottom portion of the dielectric liner has a height in a range of about 10 nm to about 20 nm.

4. The method of claim 1, wherein the etching process removes the conductive material to achieve a thickness reduction in a range of about 0.5 nm to about 1.5 nm.

5. The method of claim 1, wherein a time duration of the etching process is in a range of about 10 seconds to about 1 minute.

6. The method of claim 1, wherein the etching process is performed by using O₃ as an etching gas.

7. The method of claim 6, wherein the etching process is performed without plasma.

8. The method of claim 1, further comprising depositing a conductive layer over the dielectric liner and the conductive material after the conductive material fills the trench.

9. The method of claim 1, wherein when the conductive material fills the trench, a top portion of the dielectric liner is substantially free of the conductive material.

10. The method of claim 1, further comprising forming an isolation structure in the local interconnect structure.

11. A method comprising:
forming an isolation structure over a substrate;
forming a first transistor and a second transistor over the isolation structure and the substrate, wherein the first transistor is between the second transistor and the isolation structure;
forming a trench in gate structures of the first transistor and the second transistor and in the isolation structure;
depositing a dielectric liner to line sidewalls and a bottom of the trench;
depositing a conductive material in the trench and on the dielectric liner;
etching the conductive material, wherein a top surface of the conductive material is lower than a top surface of the isolation structure after etching the conductive material;
filling the trench with the conductive material; and
performing a planarization process to remove the dielectric liner and the conductive material outside the trench.

12. The method of claim 11, wherein the dielectric liner comprises a top portion directly over the gate structures of the first transistor and the second transistor, and after filling the trench with the conductive material, the top portion of the dielectric liner is substantially free of the conductive material.

13. The method of claim 11, wherein prior to etching the conductive material, the conductive material exposes an inner sidewall of a sidewall portion of the dielectric liner.

14. The method of claim 11, wherein the dielectric liner comprises a top portion directly over the gate structures of the first transistor and the second transistor, and after depositing the conductive material, the conductive material exposes a top surface of the top portion of the dielectric liner.

15. The method of claim 11, wherein the top surface of the conductive material is convex after etching the conductive material.

16. A device comprising:
a first channel structure and a second channel structure arranged along a first direction;
a first gate structure covering the first channel structure and extending lengthwise along the first direction;
a second gate structure covering the second channel structure and extending lengthwise along the first direction;
a first source/drain structure and a second source/drain structure connected to the first channel structure and on opposite sides of the first gate structure; and
an interconnect structure comprising:
a dielectric liner interfacing the first gate structure and the second gate structure; and
a conductive material in contact with the dielectric liner and electrically connected to the first source/drain structure and extending lengthwise along a second direction different from the first direction.

17. The device of claim 16, further comprising
an isolation structure embedded in the interconnect structure.

18. The device of claim 17, wherein the isolation structure is sandwiched between the first gate structure and the second gate structure.

19. The device of claim 17, wherein a portion of the conductive material extends beneath the isolation structure.

20. The device of claim 17, wherein a top surface of the isolation structure is substantially coplanar with a top surface of the interconnect structure.
